(19) United States
(12) Patent Application Publication
(10) Pub. No.: US 2014/0319967 A1
(43) Pub. Date: Oct. 30, 2014

(54) OSCILLATION ACTUATOR

(71) Applicant: KABUSHIKI KAISHA TOYOTA JIDOSHOKKI, Kariya-shi, Aichi (JP)

(72) Inventors: Shinya Asai, Kariya-shi (JP); Masaki Takasan, Kariya-shi (JP); Akihiro Suzuki, Kariya-shi (JP); Yasuyuki Goda, Kariya-shi (JP); Wataru Makishi, Kariya-shi (JP)

(73) Assignee: KABUSHIKI KAISHA TOYOTA JIDOSHOKKI, Kariya-shi, Aichi (JP)

(21) Appl. No.: 14/365,433

(22) PCT Filed: Dec. 7, 2012
(86) PCT No.: PCT/JP2012/081743

§ 371 Date: Jun. 13, 2014

(30) Foreign Application Priority Data
Dec. 16, 2011 (JP) 2011-275938
Dec. 28, 2011 (JP) 2011-289153
Feb. 2, 2012 (JP) 2012-021096
Feb. 13, 2012 (JP) 2012-028525

(51) Int. Cl. H02N 2/16; H02N 2/00; H01L 41/09

(52) U.S. Cl. CPC H02N 2/16; H01L 41/09; H02N 2/0065
USPC 310/328

(57) ABSTRACT

The oscillation actuator of the invention uses ultrasonic vibrations generated in a stator to rotate a rotor, and a pre-load member causes a 30 MPa contact pressure between the rotor and the stator. Furthermore, a supply body impregnated with oil is provided inside a recess section in the stator, such that the contact section between the rotor and the stator is lubricated by oil supplied from the supply body. As the oil with which the supply body is impregnated, a fluorine-based oil having a kinetic viscosity at 40° C. of VG 400 according to the ISO viscosity classification is selected.

### TECHNICAL FIELD

This invention relates to an oscillation actuator which drives a moving element using ultrasonic vibrations generated in an oscillator.

### BACKGROUND ART

In recent years, oscillation actuators have been proposed, which generate ultrasonic vibrations in an oscillator including a piezoelectric element and thereby drive a moving element pressed in contact with the oscillator by means of the frictional force between the oscillator and the moving element. In an oscillation actuator, if there is a change in the pressure contact force between the oscillator and the moving element, due to wear of the sliding portions thereof, then variation occurs in the characteristics, such as torque, the number of revolutions, etc. Therefore, in order to prevent or reduce such variation in the characteristics, it is common to use, for example, a solid lubricant such as molybdenum disulphide or graphite, to lubricate the sliding portions.

Patent Document 1, for example, describes an ultrasonic motor (oscillation actuator) provided with a rotor (moving element) to which a pivot member is fixed, and a vibrating body (oscillator), wherein the rotor is pressed in contact with the vibrating body, by a pressuring spring for energizing the pivot member. In the ultrasonic motor, nickel plating containing a solid lubricant is applied to at least one of the pivot member or the pressuring spring, with the purpose of reducing the wear of the sliding portions between the pivot member and the pressuring spring.

Patent Document 1: Japanese Patent Application Publication No. H11-196591

### DISCLOSURE OF THE INVENTION

As described above, since the oscillation actuator uses the frictional force acting between the moving element and the oscillator to drive the moving element, then in order to improve durability, it is necessary to reduce the wear of the sliding portions between the moving element and the oscillator by lubricating the sliding portions. On the other hand, in order to raise the drive torque of the moving element, it is necessary to raise the pressure contact force between the moving element and the oscillator to make the frictional force between the moving element and the oscillator greater. And the increase in the frictional force brings in an increase in the wear of the sliding portions. More specifically, in an oscillation actuator, improving durability and increasing the torque are in the relationship of trade-off.

Here, as described in Patent Document 1, it is common to provide a solid lubricant in the sliding portions, either as a layer mixed into plating, or as a layer mixed into a coating or resin film, etc. However, these layers provided on the sliding portions between the moving element and the oscillator, cracks or defects may occur in the layers if the pressure contact force between the moving element and the oscillator is too high. In other words, when using a solid lubricant to lubricate the sliding portion between the moving element and the oscillator, it is difficult to increase the torque while guaranteeing durability. Because the upper limit value of the pressure contact force between the moving element and the oscillator is limited by the hardness or the adhesiveness of the layers.

This invention was devised in order to resolve the above problems, the object thereof being to provide an oscillation actuator that achieves both improved durability and increased torque.

The inventor of the present application focused in particular on the use of liquid lubricant for lubrication between a moving element and an oscillator in order to resolve the problem described above, and as a result of continuous and thorough research and development, found new knowledge that both improved durability and increased torque can be achieved simultaneously, if the pressure contact force between the moving element and the oscillator, and the characteristics of the liquid lubricant, satisfy prescribed conditions, thereby completing the present invention.

In other words, the oscillation actuator relating to this invention includes: a moving element; an oscillator capable of making contact with the moving element; a pre-load unit which pressures and causes contact between the moving element and the oscillator; an oscillation unit which causes the moving element to move by generating ultrasonic vibrations in the oscillator; and a lubricant supply unit capable of supplying liquid lubricant between the moving element and the oscillator, wherein the pre-load unit pressures and causes contact between the moving element and the oscillator in such a manner that the contact pressure in a range of 10 MPa to 100 MPa acts between the moving element and the oscillator, the kinetic viscosity at 40° C. of the liquid lubricant is in a range of VG 200 to VG 1200 according to the ISO viscosity classification, and the surface tension of the liquid lubricant is in a range of 15 mN/m to 25 mN/m.

The lubricant supply unit may be a supply body which is impregnated with the liquid lubricant and is provided so as to be able to contact at least one of the moving element and the oscillator.

Furthermore, the supply body may be a porous member.

The contact pressure may be in a range of 30 MPa to 60 MPa.

Moreover, the kinetic viscosity at 40° C. of the liquid lubricant may be in a range of VG 400 to VG 800 according to the ISO viscosity classification.

The lubricant supply unit supplies a grease having the liquid lubricant as a base oil, in between the moving element and the oscillator.

Furthermore, the oscillator may have an abutting surface which contacts the moving element; the moving element may have an opposing surface which contacts the abutting surface of the oscillator; and the opposing surface of the moving element may have a recess section.

Moreover, the opposing surface of the moving element may have a smooth portion which makes surface contact with the abutting surface of the oscillator, and the recess section may have a plurality of holes capable of holding lubricant.

Furthermore, the recess section may have at least one groove formed in the opposing surface of the rotating element and capable of holding lubricant.

Moreover, the recess section may have a plurality of grooves, and the grooves may have a plurality of intersecting groove directions.

Furthermore, the oscillator may have a projecting claw section which projects; the abutting surface may be formed on one portion of a surface of the projecting claw section; the lubricant supply unit may contact at least one portion of the projecting claw section; and the abutting surface may have a plurality of grooves capable of holding lubricating oil.

Moreover, the vibration of the oscillation unit can be controlled in such a manner that an antinode position of the vibration or the vicinity of the antinode of the vibration is contained in the abutting surface of the oscillator.

Furthermore, the moving element may have a moving element-side contact surface capable of contacting the oscillator; the oscillator may have an oscillator-side contact surface capable of contacting the moving element-side contact surface; and the ratio (A/B) between a hardness (A) of the moving element-side contact surface and a hardness (B) of the oscillator-side contact surface may be greater than 1 and no greater than 20.

Mover, the oscillator may have amounting section which contacts the moving element; the moving element may have a cylindrical shape to rotate in contact with the mounting section of the oscillator, and have an opposing surface which contacts the mounting section of the oscillator; and a point contact region where the oscillator and the moving element make point contact in a thickness direction of the moving element may be provided in the region of opposition between the mounting section of the oscillator and the opposing surface of the moving element.

Furthermore, the point contact region may be provided by forming a curved surface which is curved in the thickness direction of the moving element, or a tapered surface which is inclined with respect to the thickness direction of the moving element, in the mounting section of the oscillator.

According to this invention, it is possible to achieve both improved durability and increased torque in an oscillation actuator.

### BRIEF DESCRIPTION OF THE DRAWINGS

FIG. 1 is a perspective diagram showing a composition of an oscillation actuator relating to a first or second embodiment of the invention;

FIG. 2 relates to an oscillation actuator relating to a first embodiment, wherein FIG. 2(a) is a graph showing the evolution of the drive torque with respect to the kinetic viscosity of a liquid lubricant, and FIG. 2(b) is a graph showing the evolution of the amount of wear of the contact region between a moving element and a fixed element, with respect to the kinetic viscosity of the liquid lubricant;

FIG. 3 is a graph relating to an oscillation actuator relating to the first embodiment, showing a correlation between the type of liquid lubricant and the drive torque of the oscillation actuator;

FIG. 4 is a conceptual diagram relating to the oscillation actuator shown in FIG. 1, showing a case where the torque of the moving element is plotted on the vertical axis and the ratio of the hardness of the rotor/hardness of the stator is plotted on the horizontal axis;

FIG. 5 is a conceptual diagram relating to the oscillation actuator shown in FIG. 1, in which the volume of a piezoelectric element is plotted on the x axis, the magnitude of the frictional force acting between the rotor and the stator is plotted on the y axis, and the magnitude of a pre-load is plotted on the z axis, and the volume of the graph represents the torque of the moving element;

FIG. 6 is a perspective diagram showing a configuration of an oscillation actuator relating to a third embodiment of the present invention;

FIG. 7 is a schematic drawing showing a roughness curve and surface state of a cylindrical surface of a rotor in the oscillation actuator shown in FIG. 6;

FIG. 8 is a perspective diagram showing a configuration of an oscillator actuator relating to a fourth embodiment of the present invention;

FIG. 9 is an expanded diagram and an enlarged diagram showing the shape of the whole cylindrical surface of the rotor in the oscillation actuator shown in FIG. 8;

FIG. 10 is an expanded diagram and an enlarged diagram showing modifications of the shape of the whole cylindrical surface of the rotor in the oscillation actuator shown in FIG. 8;

FIG. 11 is a perspective diagram showing a configuration of an oscillator in the oscillation actuator relating to a fifth embodiment of the present invention;

FIG. 12 is a plan diagram showing a state of the oscillator shown in FIG. 11 viewed from above;

FIG. 13 is a schematic drawing showing the shape of all the grooves provided in a portion of an abutting surface of the oscillator shown in FIG. 11;

FIG. 14 is a schematic drawing showing modifications of the shape of all the grooves provided in one portion of the abutting surface of the oscillator shown in FIG. 11;

FIG. 15 is a perspective diagram showing a configuration of an oscillation actuator relating to a sixth embodiment of the invention;

FIG. 16 is a perspective diagram showing a modification of the oscillator actuator relating to this invention;

FIG. 17 is a perspective diagram showing a modification of the oscillator actuator relating to this invention;

FIG. 18 is a perspective diagram showing a modification of the oscillator actuator relating to this invention;

FIG. 19(a) is a front face diagram of the oscillation actuator relating to a seventh embodiment of the invention, as viewed in the radial direction of the rotor; and FIG. 19B is a partial perspective diagram showing an enlarged view of a region of opposition between the stator and the rotor;

FIG. 20 is a side face diagram of the oscillation actuator shown in FIG. 19;

FIG. 21 is a cross-sectional diagram along line A-A in FIG. 20 of the oscillation actuator shown in FIG. 19;

FIG. 22A is a partial enlarged front face diagram of the oscillation actuator shown in FIG. 19; FIG. 22(b) is a cross-sectional diagram along line B-B in FIG. 20; FIG. 22(c) is a cross-sectional diagram along line C-C in FIG. 22A; and FIG. 22(d) is a cross-sectional diagram along line D-D in FIG. 22A;

FIG. 23 is a partial cross-sectional diagram showing an enlarged view of a region of opposition between the stator and rotor in a modification of the oscillation actuator relating to the invention; and

FIG. 24 is a partial cross-sectional diagram showing an enlarged view of a region of opposition between the stator and rotor in a modification of the oscillation actuator relating to the invention.

### BEST MODE FOR CARRYING OUT THE INVENTION

Embodiments of the invention are described below with reference to the accompanying drawings.

### First Embodiment

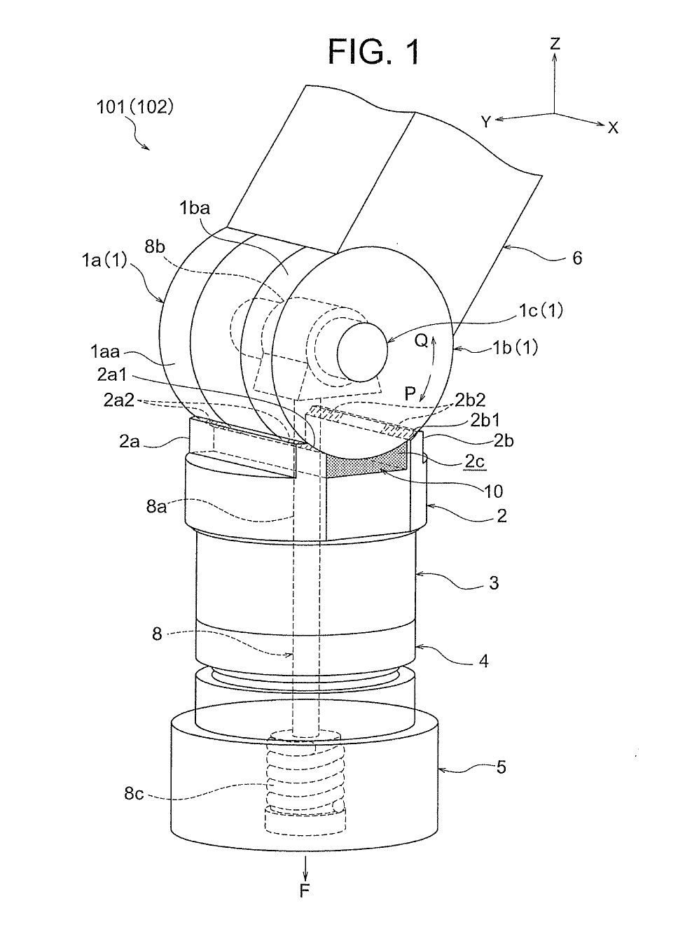

FIG. 1 shows an oscillation actuator 101 relating to this first embodiment. The oscillation actuator 101 causes a substantially cylindrical rotor 1 to rotate about an axial direction (see arrow P and arrow Q) using ultrasonic vibration, and is provided with an oscillator 2 which contacts the rotor 1 at one end side thereof. Furthermore, on the other end side of the oscillator 2, a piezoelectric element 3 which generates an ultrasonic vibration in the oscillator 2, and a first base block 4 and a second base block 5, are provided in this manner. The piezoelectric element 3 is formed by laminating together a plurality of piezoelectric plates, and ultrasonic vibrations are generated in the oscillator 2 by applying an AC voltage to the piezoelectric element plates, from a drive circuit (not illustrated). The oscillator 2 and the piezoelectric element 3 have a substantially cylindrical outer shape overall, and the axis direction of the rotor 1 is perpendicular to the axis directions of the oscillator 2 and the piezoelectric element 3. Here, the rotor 1, the oscillator 2 and the piezoelectric element 3 respectively constitute the moving element, the oscillator and the oscillation unit in the oscillation actuator 101.

The rotor 1 includes a first rotor section 1a and a second rotor section 1b, which have the same cylindrical shape, and a rotor shaft 1c that passes through a central portion of the first rotor sections 1a and the second rotor section 1b. The first rotor section 1a and the second rotor section 1b are integrally fixed to both ends of the rotor shaft 1c respectively, in such a manner that the first rotor section 1a, the second rotor section 1b and the rotor shaft 1c are integrally rotated along the central axis of the rotor shaft 1c. Furthermore, if the oscillation actuator 101 is applied to a robot hand, for example, a bar-shaped arm member 6 constituting arm parts or finger parts is provided on the outer circumference portion of the rotor 1. The arm member 6 is fixed respectively to an outer circumferential surface 1aa of the first rotor section 1a and an outer circumferential surface 1ba of the second rotor section 1b, and the rotor 1 and the arm member 6 can integrally rotate. The outer circumferential surface 1aa of the first rotor section 1a and the outer circumferential surface 1ba of the second rotor section 1b constitute opposing surfaces.

Here, for the purposes of the description given below, the central axes of the oscillator 2 and the piezoelectric element 3 are specified as the Z axis, and the positive direction on this axis is set as the direction from the second base block 5 side towards the oscillator 2. Furthermore, the central axis of the rotor shaft 1c which is orthogonal to the Z axis is specified as the X axis, and moreover, a Y axis is specified as extending in orthogonal to both the Z axis and the X axis.

A first projecting claw section 2a and a second projecting claw section 2b are formed projecting in the positive direction along the Z axis and extending in a linear shape along the X axis, at an end portion of the oscillator 2 on the rotor 1 side. Furthermore, a supply body 10 impregnated with oil, which is described in detail below, is provided inside a recess 2c formed between the first projecting claw section 2a and the second projecting claw section 2b.

A first abutting surface 2a1 having a circular arc-shaped cross-section following the outer circumferential surface 1aa of the first rotor section 1a and the outer circumferential surface 1ba of the second rotor section 1b is formed on the inner side of the front end portion of the first projecting claw section 2a, in other words, on the portion thereof situated on the side of the recess 2c, and this first abutting surface 2a1 contacts the outer circumferential surface 1aa of the first rotor section 1a and the outer circumferential surface 1ba of the second rotor section 1b. Similarly, a second abutting surface 2b1 having a circular arc-shaped cross-section similar to that of the first abutting surface 2a1 is formed on the inner side portion of the front end portion of the second projecting claw section 2b, and this second abutting surface 2b1 contacts the outer circumferential surface 1aa of the first rotor section 1a and the outer circumferential surface 1ba of the second rotor section 1b. In other words, the oscillator 2 can make surface contact with the first rotor section 1a and the second rotor section 1b of the rotor 1, on the first abutting surface 2a1 of the first projecting claw section 2a and the second abutting surface 2b1 of the second projecting claw section 2b.

Furthermore, the first abutting surface 2a1 has a pair of first contact surfaces 2a2, and also contacts the outer circumferential surface 1aa of the first rotor section 1a and the outer circumferential surface 1ba of the second rotor section 1b at these first contact surfaces 2a2. Moreover, the second abutting surface 2b1 has a pair of second contact surfaces 2b2, and also contacts the outer circumferential surface 1aa of the first rotor section 1a and the outer circumferential surface 1ba of the second rotor section 1b at these second contact surfaces 2b2.

Here, the outer circumferential surface 1aa of the first rotor section 1a and the outer circumferential surface 1ba of the second rotor section 1b constitute moving element side contact surfaces. The moving element side contact surfaces are portions where the rotor 1 can make contact with the stator 2 in accordance with the range of rotational movement of the rotor 1. In the present embodiment, the moving element side contact surfaces means the whole of the outer circumferential surface 1aa and the outer circumferential surface 1ba, apart from the portion where the arm member 6 is installed.

Furthermore, the first contact surfaces 2a2 and the second contact surfaces 2b2 constitute oscillator side contact surfaces. These oscillator side contact surfaces mean the portions of the stator which can make contact with the rotor.

Moreover, the oscillation actuator 101 is provided with a pre-load member 8 for creating pressured contact between the rotor 1 and the oscillator 2. The pre-load member 8 has a shaft section 8a extending along the Z axis in the central portion of the oscillator 2 and the piezoelectric element 3. One end of the shaft section 8a projects from the oscillator 2 and extends between the first rotor section 1a and the second rotor section 1b of the rotor 1, and is coupled to an attaching section 8b which is supported rotatably so as to surround the outer circumferential portion of the rotor shaft 1c. On the other hand, the other end of the shaft section 8a projects inside the second base block 5, and is coupled to an urging section 8c composed of a coil spring, or the like. The urging section 8c urge the rotor shaft 1c in the direction indicated by arrow F (the negative direction along the Z axis) via the shaft section 8a and the attaching section 8b, whereby the rotor 1 and the oscillator 2 are caused to make pressure contact.

Here, the contact pressure acting between the rotor 1 and the oscillator 2 due to the pressure contact created by the pre-load member 8, in other words, the surface pressure acting between the outer circumferential surface 1aa of the first rotor section 1a, and the outer circumferential surface 1ba of the second rotor section 1b and the first abutting surface 2a1 of the first projecting claw section 2a, and the second abutting surface 2b1 of the second projecting claw section 2b, is set in a range of 10 MPa to 100 MPa, and more desirably, 30 MPa to 60 MPa. The pre-load member 8 which is composed of the shaft section 8a, the attaching section 8b and the urging section 8c constitutes a pre-load unit in the oscillation actuator 101.

Next, the supply body 10 which is provided in the recess 2c of the oscillator 2, and the characteristics of the oil with which the supply body 10 is impregnated, will be described.

The supply body 10 is a substantially cuboid member made from a porous resin having flexibility, which is provided in such a manner that both side surfaces thereof are respectively adjacent to and make contact with the first projecting claw section 2a and the second projecting claw section 2b of the oscillator 2. Furthermore, the upper surface of the supply body 10 makes contact with the outer circumferential surface 1aa of the first rotor section 1a and the outer circumferential surface 1ba of the second rotor section 1b in the whole of the area between a position adjacent to the first projecting claw section 2a and a position adjacent to the second projecting claw section 2b. On the other hand, the bottom surface of the supply body 10 makes contact with the bottom wall surface of the recess 2c over the whole surface thereof. Here, the rotor 1 makes pressure contact with the oscillator 2 due to being urged in the direction indicated by arrow F by the pre-load member 8. The supply body 10 is pressed by the first rotor section 1a and the second rotor section 1b of the rotor 1, and is supported inside the recess 2c by being deformed into a shape following the outer circumferential surface 1aa and the outer circumferential surface 1ba thereof.

The supply body 10 which is composed in this way is impregnated with oil, which is a liquid lubricant. This oil is absorbed by and held in the supply body 10 by capillary action in the continuous pore structure of the resin which forms the supply body 10, and due to the supply body 10 making contact with the first rotor section 1a and the second rotor section 1b of the rotor 1, the oil is supplied to the outer circumferential surface 1aa and the outer circumferential surface 1ba of the rotor sections 1a and 1b. Here, the oil selected for use in the oscillation actuator 101 is an oil having a viscosity at 40° C. in a range of VG 200 to VG 1200 according to the ISO viscosity classification, and more desirably, in a range of VG 400 to VG 800, and having a surface tension in a range of 15 mN/m to 25 mN/m.

The porous resin forming the supply body 10 becomes impregnated with a larger amount of oil, the higher the porosity, and the larger the pore diameter. In other words, it is desirable to employ a resin having a high porosity, such as a PVA resin (polyvinyl alcohol), or the like, which has a porosity of about 90% or above, for example, as the resin forming the material of the supply body 10. Furthermore, by selecting a resin having a desired porosity, it is possible to set the amount of oil supplied.

As described above, the oscillation actuator 101 according to the first embodiment is composed in such a manner that the contact pressure acting between the rotor 1 and the oscillator 2, and the characteristics of the oil lubricating the rotor 1 and the oscillator 2, satisfy the conditions (1) to (3) indicated below.

(1) The contact pressure acting between the rotor 1 and the oscillator 2 is in a range of 10 MPa to 100 MPa, and more desirably, a range of 30 MPa to 60 MPa.

(2) The kinetic viscosity at 40° C. of the oil used for lubrication between the rotor 1 and the oscillator 2 is in a range of VG 200 to VG 1200, and more desirably, VG 400 to VG 800, according to ISO viscosity classification.

(3) The surface tension of the oil is in a range of 15 mN/m to 25 mN/m.

The action of each of these conditions (1) to (3) is described below.

First, in respect of condition (1) above, if oil is used as a liquid lubricant for lubrication between the rotor 1 and the oscillator 2, and the lubrication between the rotor 1 and the oscillator 2 achieves a fluid lubricated state, in other words, if the surfaces of the contact portions of the rotor 1 and the oscillator 2 do not contact each other due to the formation of a layer of oil (oil film) between the surfaces, then wear is reduced, while the frictional force between the rotor 1 and the oscillator 2 is dramatically reduced. In other words, if the rotor 1 and the oscillator 2 are in a fluid lubricated state, then it is difficult to drive the rotor 1 with a high torque.

Therefore, if the frictional force is to be ensured while reducing the wear of the rotor 1 and the oscillator 2, then it is necessary to achieve a borderline lubricated state between the rotor 1 and the oscillator 2, in other words, a state in which the surfaces of the rotor 1 and the oscillator 2 make contact with each other at least partially, and an oil film is formed in the remaining portions thereof. Here, the amplitude of the ultrasonic vibrations generated in the oscillator 2 by the oscillation actuator 101 is approximately 1 μm to 2 μm. In other words, if the thickness of the oil film formed between the rotor 1 and the oscillator 2 is no greater than 1 μm, then it is possible to achieve a borderline lubricated state between the rotor 1 and the oscillator 2, and it has been confirmed that if the contact pressure acting between the rotor 1 and the oscillator 2 due to the pre-load member 8 satisfies condition (1) above, then the thickness of the oil film becomes no greater than 1 μm.

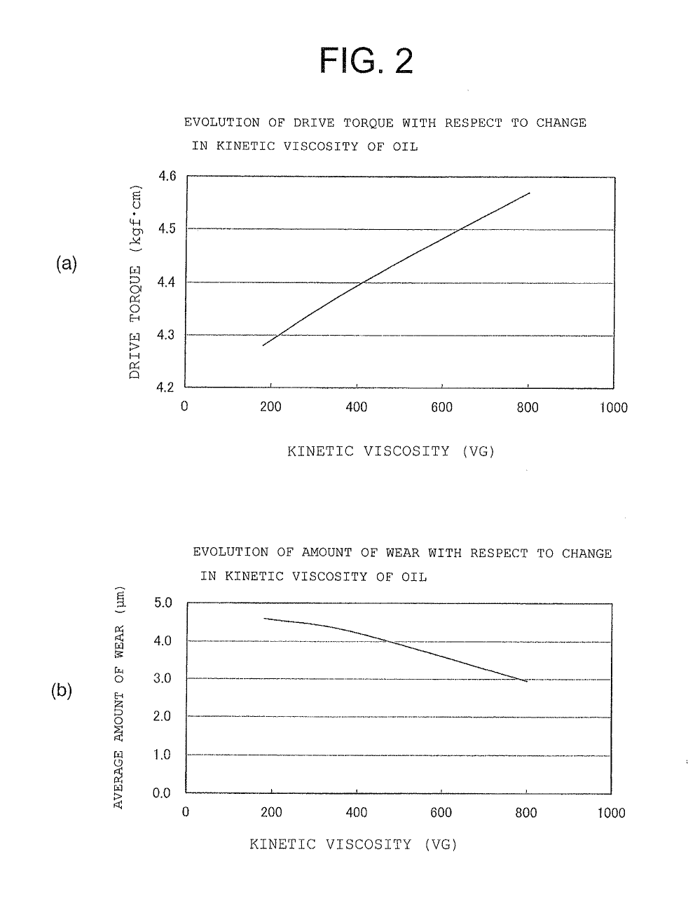

Next, with respect to condition (2) stated above, if an oil film no greater than 1 μm is formed between the rotor 1 and the oscillator 2, then the drive force between the rotor 1 and the oscillator 2 is transmitted by using the shear force of the oil, and therefore it is desirable that the kinetic viscosity of the oil should be high. In this respect, FIG. 2A shows a graph of an experiment investigating the evolution of the drive force transmitted from the oscillator 2 to the rotor 1, in other words, the drive torque of the rotor 1, when the kinetic viscosity of the oil was changed in steps from VG 180 to VG 800. Furthermore, FIG. 2(b) shows a graph of an experiment investigating the evolution of the wear of the contacting portions of the rotor 1 and the oscillator 2, when the kinetic viscosity of the oil was changed in steps from VG 180 to VG 800. With regard to the experimental conditions, the contact pressure acting between the rotor 1 and the oscillator 2 was set to 30 MPa, and a fluorine-based oil was used for lubrication. Furthermore, the average amount of wear represented by the vertical axis in FIG. 2(b) indicates the average amount of wear when the rotor 1 is rotated 1,000,000 times under these conditions.

As shown in the graph in FIG. 2A, the drive torque of the rotor 1 increases as the kinetic viscosity of the oil increases. On the other hand, as shown by the graph in FIG. 2(b), the amount of wear in the contact portions between the rotor 1 and the oscillator 2 gradually decreases as the kinetic viscosity of the oil increases. From these graphs, it is clear that a desirable kinetic viscosity for the oil is no less than VG 200, and it is also clear that the kinetic viscosity is more desirably set to no less than VG 400. The kinetic viscosity of oil is specified from VG2 to VG 1500 according to the ISO viscosity classification (at 40° C.), but oil exceeding VG 1200 is generally used for special applications, and is highly expensive. Furthermore, if the kinetic viscosity is relatively high, then there is a risk of decrease in the speed when driven at low temperature. More specifically, if the kinetic viscosity of the oil is in a range of VG 200 to VG 1200, and more desirably, VG 400 to VG 800, then it is possible to achieve an optimal balance between the drive torque and the amount of wear, at low cost.

Furthermore, with regard to condition (3) stated above, if the rotor 1 and the oscillator 2 are lubricated with oil, then the oil used must have sufficient wetting properties to enter in between the rotor 1 and the oscillator 2, in other words, the oil must have low surface tension. In this respect, to give examples of the surface tensions of principal oils, mineral oil has a surface tension of 29.7 mN/m, toluene has a surface tension of 28.4 mN/m, silicone oil has a surface tension of 20 to 21 mN/m, and fluorine-based oil has a surface tension of 19.1 mN/m. In other words, of the abovementioned oils, silicone oil and fluorine-based oil have a low surface tension, and condition (3) stated above is satisfied if one of these oils is selected.

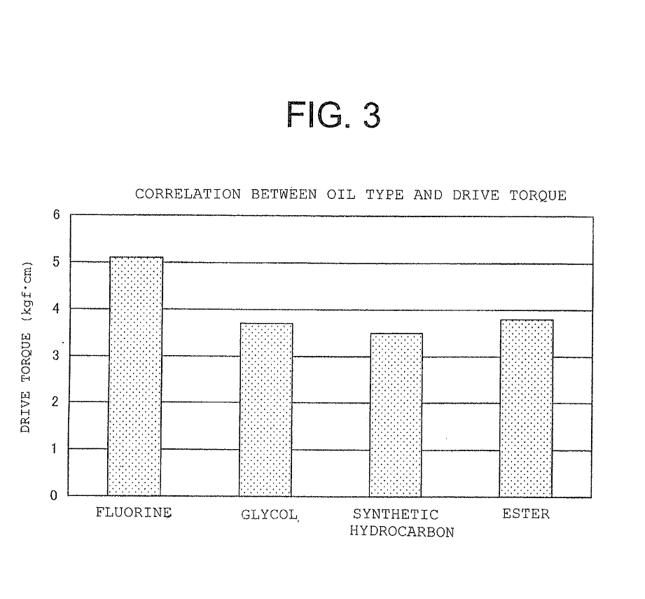

From the foregoing, the oscillation actuator 101 according to the first embodiment is constructed in such a manner that the contact pressure acting between the rotor 1 and the oscillator 2 due to the pre-load member 8 is 30 MPa. Furthermore, fluorine oil which has a kinetic viscosity of VG 400 is chosen as the oil for providing lubrication between the rotor 1 and the oscillator 2. In this regard, FIG. 3 shows the results of an experiment investigating the evolution of the drive torque of the rotor 1, in a case where the contact pressure acting between the rotor 1 and the oscillator 2 is 30 MPa, and the rotor 1 and the oscillator 2 are lubricated by using oils of a plurality of types having a kinetic viscosity of VG 400. Apart from fluorine-based oil which is used in the oscillation actuator 101, a glycol-based oil, synthetic hydrocarbon-based oil and ester-based oil were used in the experiment. From FIG. 3, it is clear that a good drive torque is obtained when fluorine oil is used. In other words, from FIG. 2A, FIG. 2 (b) and FIG. 3, it is clear that both improved durability and increased torque can be achieved in the oscillation actuator 101 if the conditions (1) to (3) described above are satisfied. In particular, the oscillation actuator 101 relating to the present invention can maintain a favorable balance between durability and drive torque when applied to a robot hand which is driven at a relatively low speed of revolution and requires high drive torque.

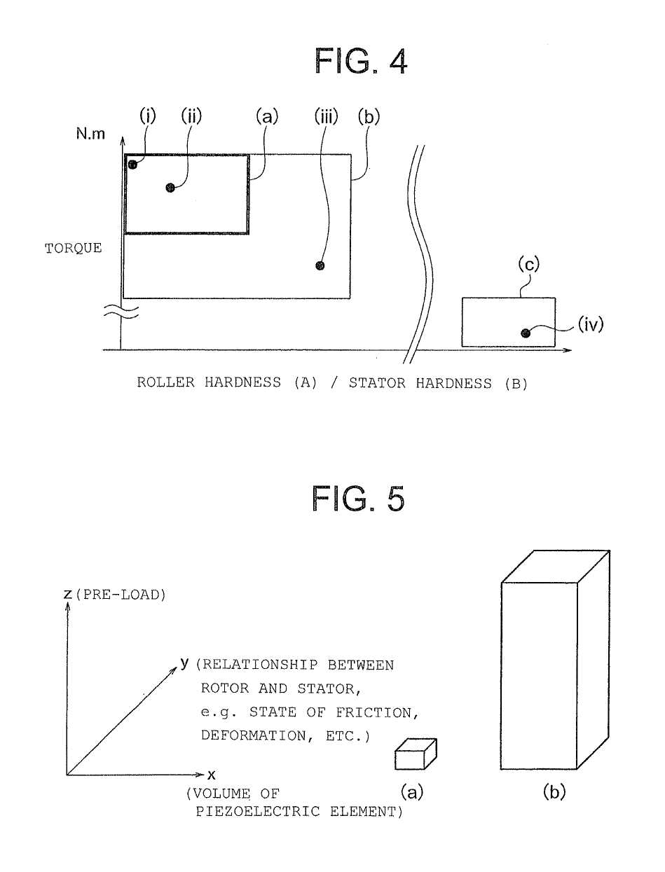

Next, the hardness (A) of the rotor 1 and the hardness (B) of the stator 2 in the oscillation actuator 101 will be described with reference to FIGS. 4 and 5. The ratio (A/B) between the hardness (A) of the rotor 1 and the hardness (B) of the stator 2 is configured to be greater than 1 and no greater than 5.

FIG. 4 is a graph showing a conceptual view of the relationship between the ratio (A/B) between the hardness (A) of the rotor 1 and the hardness (B) of the stator 2, and the torque of the rotor. The hardness values of the rotor 1 and the stator 2 are measured using a generic hardness analyzer on the basis of the same indicators. The hardness in the present embodiment is a value based on Vickers hardness, but it is also possible to use Rockwell hardness values, or the like.

In this graph, ceramic is used as the material of the rotor 1, and has a Vickers hardness value of HV 1700. In FIG. 4, (i) indicates a case where ceramic was used as the material of the stator 2. Furthermore, (ii) and (iii) respectively indicate cases where steel carbide and aluminum were used as the material of the stator 2.

Moreover, region (a) in the graph in FIG. 4 indicates a region where the ratio (A/B) between the hardness (A) of the rotor 1 and the hardness (B) of the stator 2 is greater than 1 and no greater than 5. In this respect, in the present embodiment, the ratio (A/B) between the hardness (A) of the rotor 1 and the hardness (B) of the stator 2 has a value greater than 1 and no greater than 5, and is represented by the interior of the region (a). Furthermore, the cases (i) and (ii) described above are both inside the region (a).

Moreover, region (b) indicates a region where the hardness ratio (A/B) is greater than 1 and no greater than 20. Here, case (iii) lies outside region (a) and inside region (b); the hardness ratio (A/B) when aluminum is used for the material of the stator 2 is greater than 5 and no greater than 20.

Furthermore, (iv) indicates the ratio (A/B) between the hardness (A) of the rotor 1 and the hardness (B) of the stator 2 in a conventional oscillation actuator using resin material for the stator 2, and region (c) indicates the range of the hardness ratio (A/B) and torque envisaged when a resin material is used for the rotor 1.

From region (c) in FIG. 4, it is evident that if a resin material is used for the stator 2, then the ratio (A/B) between the hardness (A) of the rotor 1 and the hardness (B) of the stator 2 becomes extremely large, and therefore it is not possible to obtain the required high torque. More specifically, in the region (c), the hardness (B) of the stator 2 is too low compared to the hardness (A) of the rotor 1, and therefore pre-load is only possible up to 10N, which means that a high torque cannot be obtained.

On the other hand, in the region (a), there is little difference between the hardness (A) of the rotor 1 and the hardness (B) of the stator 2, and since the hardness ratio (A/B) is small, then an extremely high pre-load force (300 N to 600 N) can be applied. Consequently, a sufficiently high torque to enable direct driving of the arm member 6 is generated in the oscillation actuator 101.

Next, the difference between the torque of the oscillation actuator 101 according to the present invention and a conventional oscillation actuator using resin material for the stator 2 is described with reference to FIG. 5. FIG. 5 shows a conceptual view of the magnitude of the torque of the oscillation actuator which is represented by the volume of a three-dimensional graph derived by respectively plotting the volume of the piezoelectric element on the x axis, a coefficient representing the relationship between the rotor and the stator on the y axis, and the pre-load force on the z axis. The coefficient representing the relationship between the rotor and the stator is a coefficient which changes in accordance with the extent of the friction between the rotor and the stator, and the extent of deformation, and if the coefficient of friction is large, then this coefficient increases, the smaller the amount of deformation is.

Here, FIG. 5A shows the magnitude of the torque of the oscillation actuator, in which resin is used as the material of the stator 2. Furthermore, FIG. 5B shows the magnitude of the torque of the oscillation actuator 101 relating to the present invention. As described above, the oscillation actuator 101 in FIG. 5B has a low pre-load force compared to the oscillation actuator in FIG. 5A. Furthermore, the oscillation actuator in FIG. 5A is used in a clock or camera, as described above, and therefore the piezoelectric element is small. Moreover, the coefficient representing the relationship between the stator and rotor is also small. Consequently, it can be seen that a higher torque is obtained in the case of the oscillation actuator 101 shown in FIG. 5B.

Furthermore, by setting the ratio (A/B) between the hardness (A) of the rotor 1 and the hardness (B) of the stator 2 to be greater than 1 and no greater than 5, the rotor 1 does not wear, and smooth operation of the oscillation actuator 101 is maintained even over long-term use. Furthermore, the difference in hardness between the rotor 1 and the stator 2 does not become too large, and it is possible to apply a high pre-load force. As a result of this, it is possible to obtain the high torque required to drive the arm member 6. In other words, even if the oscillation actuator 101 is used for a long period of time, both smooth operation and increased torque can be achieved.

The ratio (A/B) between the hardness (A) of the rotor 1 and the hardness (B) of the stator 2 is not limited to that of the present embodiment. In particular, the ratio (A/B) between the hardness (A) of the rotor 1 and the hardness (B) of the stator 2 may be greater than 5 and no greater than 20, in which case, similar beneficial effects are obtained to when the ratio (A/B) between the hardness (A) of the rotor 1 and the hardness (B) of the stator 2 is greater than 1 and no greater than 5. Furthermore, the rotor 1 and the stator 2 may also be of the same hardness.

Next, the operation of the oscillation actuator relating to the first embodiment of this invention will be described.

As shown in FIG. 1, first, if an AC voltage is applied to the plurality of piezoelectric element plates of the piezoelectric element 3 from the drive circuit (not illustrated), then each of the piezoelectric element plates respectively generate ultrasonic vibrations in mutually different vibration directions. When these ultrasonic vibrations are transmitted to the oscillator 2 as a complex vibration, an elliptical vibration about the X axis is generated in the front end portions of the first projecting claw section 2a and the second projecting claw section 2b of the oscillator 2. Furthermore, a travelling wave due to the elliptical vibration about the X axis is generated in the first abutting surface 2a1 of the first projecting claw section 2a and the second abutting surface 2b1 of the second projecting claw section 2b, and due to the frictional force acting between these abutting surfaces 2a1, and 2b1 and the outer circumferential surface 1aa of the first rotor section 1a, and the outer circumferential surface 1ba of the second rotor section 1b of the rotor 1, the rotor 1 and the arm member 6 rotate in the direction indicated by the arrow P or the arrow Q. The direction of rotation of the rotor 1 is controlled in accordance with the AC voltage applied to the respective piezoelectric element plates of the piezoelectric element 3.

Oil that has impregnated into the supply body 10 in the recess 2c of the oscillator 2 is applied to the outer circumferential surface 1aa of the first rotor section 1a and the outer circumferential surface 1ba of the second rotor section 1b of the rotor 1. The oil applied to the outer circumferential surface 1aa and the outer circumferential surface 1ba enters in between the outer circumferential surface 1aa and the outer circumferential surface 1ba, and the first abutting surface 2a1 and the second abutting surface 2b1 of the oscillator 2, due to the rotation of the rotor 1. Here, since the oil impregnated into the supply body 10 is a fluorine-based oil having a low surface tension and good wetting properties, then the oil can readily enter in between the outer circumferential surface 1aa and the outer circumferential surface 1ba of the rotor 1, and the first abutting surface 2a1 and the second abutting surface 2b1 of the oscillator 2, and the oil entering therein forms an oil film between the rotor 1 and the oscillator 2 and lubricates them.

Furthermore, a contact pressure of 30 MPa acts between the rotor 1 and the oscillator 2, due to the pre-load member 8, and because of this contact pressure, the oil which has entered in between the rotor 1 and the oscillator 2 forms an oil film having a thickness of no more than 1 μm. In this case, the amplitude of the ultrasonic vibration generated in the oscillator 2 is 1 μm to 2 μm, and therefore the rotor 1 and the oscillator 2 assume a borderline lubricated state in which the surfaces of them make at least partial contact, and an oil film is formed in the remaining portions. Moreover, since the kinetic viscosity of the oil is high (VG 400 according to the ISO viscosity classification at 40° C.), then in a state where a 1-μm oil film has been formed, drive force is transmitted from the oscillator 2 to the rotor 1 by using the shear force of the oil. In other words, it is possible to cause a prescribed frictional force between the rotor 1 and the oscillator 2 while providing lubrication between the rotor 1 and the oscillator 2, and consequently, both improved durability and increased torque can be achieved in the oscillation actuator 101.

The phase of the ultrasonic vibrations generated by the piezoelectric element 3 can be controlled in accordance with the AC voltage applied to the respective piezoelectric elements, and in the oscillation actuator 101, the so-called antinode of the vibration where the vibration is greatest is controlled so as to be at or near the position of the first abutting surface 2a1 and the second abutting surface 2b1 of the oscillator 2. Therefore, the vibration at the position of the first abutting surface 2a1 and the second abutting surface 2b1 of the oscillator 2 becomes large. Moreover, the oil supply body 10 is provided in such a manner that both side faces thereof make contact with the first projecting claw section 2a and the second projecting claw section 2b of the oscillator 2, in other words, are adjacent to the first abutting surface 2a1 and the second abutting surface 2b1.

In this respect, the liquid supplied to the vicinity of the portion where ultrasonic vibration occurs has the characteristic of gathering at the position where the antinode of the ultrasonic vibration is formed. Consequently, by arranging the supply body 10 inside the recess 2c of the oscillator 2, and setting the position of the antinode of the ultrasonic vibration to be at or near the position of the first abutting surface 2a1 and the second abutting surface 2b1 of the oscillator 2, it is possible to supply oil efficiently between the rotor 1 and the oscillator 2. Furthermore, if ultrasonic vibration occurs at the first abutting surface 2a1 and the second abutting surface 2b1 of the oscillator 2, then oil is supplied between the rotor 1 and the oscillator 2, even if the rotor 1 is not rotating. Consequently, for example, when the oscillation actuator 101 is started up, it is possible to supply oil directly between the rotor 1 and the oscillator 2, and the oscillation actuator 101 can be started up smoothly and wear during start-up can be reduced.

Moreover, since the supply body 10 is held inside the recess 2c of the oscillator 2 by the force of the pre-load member 8 urging the rotor 1 against the oscillator 2, then if the material of the supply body 10 is a flexible material, such as a PVC resin, for example, then the supply body 10 can be kept to applying a low rotational resistance to the rotor 1. Furthermore, since the supply body 10 is made from a porous resin material, it is possible to select the porosity and the pore diameter, as appropriate. For example, the amount of oil applied to the rotor 1 is adjusted by changing the porosity, and consequently, worn chips generated in the contact portions between the rotor 1 and the oscillator 2 can be prevented from becoming attached to the outer circumferential surface 1aa of the first rotor section 1a and the outer circumferential surface 1ba of the second rotor section 1b. Furthermore, by selecting the pore diameter in accordance with the size of the worn chips generated in the contacting portions between the rotor 1 and the oscillator 2, the generated worn chips can be swept away by the supply body 10, making it possible to protect the outer circumferential surface 1aa of the first rotor section 1a and the outer circumferential surface 1ba of the second rotor section 1b can be protected.

As described above, in an oscillation actuator 101 in which the rotor 1 and the oscillator 2 are caused to make pressured contact by the pre-load member 8, and ultrasonic vibrations generated in the oscillator 2 are used to drive the rotor 1, since oil, which is a liquid lubricant, is used to provide lubrication between the rotor 1 and the oscillator 2, and since the contact pressure acting between the rotor 1 and the oscillator 2 is set to 30 MPa, the rotor 1 and the oscillator 2 are lubricated in a borderline lubricated state. Furthermore, since the oil used for lubrication is a fluorine-based oil having a kinetic viscosity of VG 400 according to the ISO viscosity classification, and having a low surface tension, then in the rotor 1 and the oscillator 2 which are lubricated in a borderline lubricated state, it is possible to generate a frictional force efficiently between the rotor 1 and the oscillator 2, while reducing wear. Consequently, according to the present invention, it is possible to improve the durability of the oscillation actuator 101 and to increase the torque therein.

### Second Embodiment

Next, an oscillation actuator relating to a second embodiment of the invention will be described.

The oscillation actuator 102 relating to this second embodiment is configured so as to provide lubrication by using grease, as opposed to the oscillation actuator 101 of the first embodiment which uses oil for lubrication between the rotor 1 and the oscillator 2. Therefore, the oscillation actuator 102 relating to the second embodiment has the same configuration as the oscillation actuator 101 shown in FIG. 1.

The supply body 10 of the oscillation actuator 102 is impregnated with a grease having a base oil which is the oil used in the first embodiment, to which PTFE (polytetrafluoroethylene) is added as a thickener. Here, since the characteristics of grease are normally dependent on the characteristics of the base oil, then the grease used in the oscillation actuator 102 has the same characteristics as the oil used in the oscillation actuator 101.

In this way, even if grease is used for the lubrication between the rotor 1 and the oscillator 2, provided that the condition (1) relating to the contact pressure between the rotor 1 and the oscillator 2 is satisfied, and the base oil of the grease satisfies condition (2) relating to kinetic viscosity and condition (3) relating to surface tension, then it is possible to obtain virtually the same beneficial effects as the first embodiment in respect of achieving both improved durability and increased torque. By using grease instead of oil, the friction loss when transmitting drive force between the rotor 1 and the oscillator 2 becomes higher, but the amount of lubricant flowing out from the supply body 10 is reduced accordingly.

### Third Embodiment

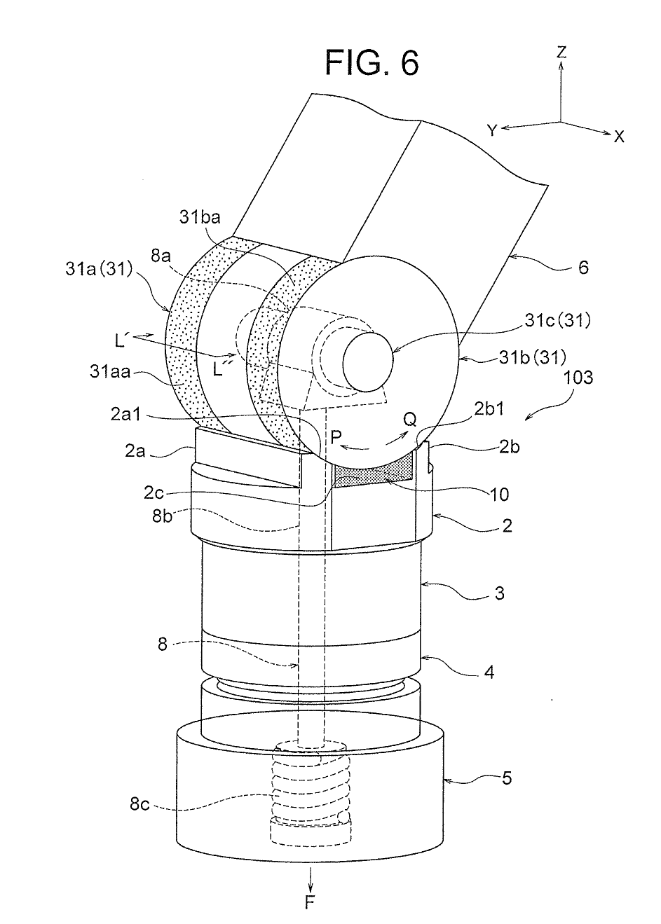

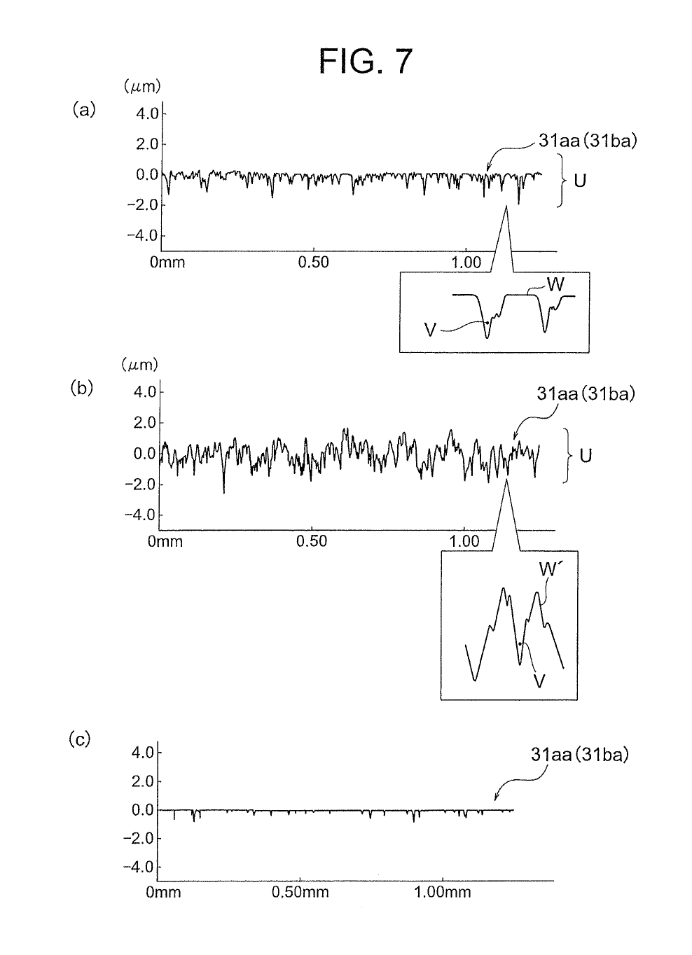

Next, the oscillation actuator relating to a third embodiment of the invention will be described with reference to FIGS. 6 and 7. The oscillation actuator 103 relating to the third embodiment has a plurality of recesses formed in the outer circumferential surfaces 1aa, 1ba of the rotor 1 of the oscillation actuator 101 relating to the first embodiment. In the embodiments described below, reference symbols which are the same as those shown in FIG. 1 indicate constituent elements which are the same or similar, and therefore detailed description thereof is omitted here. Furthermore, in particular, the liquid lubricant with which the supply body 10 is impregnated is a fluorine-based oil having a viscosity at 40° C. of VG 400 according to the ISO viscosity classification, and is composed so to satisfy conditions (2) and (3) specified in the first embodiment.

As shown in FIG. 6, the oscillation actuator 103 is provided with a rotor 31 in which a plurality of recesses are formed in an outer circumferential surface 31aa of a first rotor section 31a and an outer circumferential surface 31ba of a second rotor section 31b. The rotor 31 is pressed against the oscillator 2 by the pre-load member 8, and a contact pressure of 30 MPa acts between the rotor 31 and the oscillator 2. In other words, the oscillation actuator 103 is configured in such a manner that the contact pressure acting between the rotor 31 and the oscillator 2 satisfies a condition similar to condition (1) given in the first embodiment.

Here, FIG. 7(a) is a partial enlarged diagram showing a roughness curve of the outer circumferential surface 31aa of the first rotor section 31a viewed along the cross-section line L′-L″ shown in FIG. 6, and a schematic view of the surface state thereof. As shown in FIG. 7(a), smooth portions W constituting smooth surfaces and recesses V constituting fine holes and grooves are formed over the whole surface of the outer circumferential surface 31aa. The smooth portions W are formed in such a manner that the distance from the centre of the first rotor section 31a to each portion of the outer circumferential surface 31aa is uniform, and these smooth portions W make surface contact with the first abutting surface 2a1 and the second abutting surface 2b1 of the oscillator 2 described below. Furthermore, the recesses V are portions which are recessed in the opposite direction from the first abutting surface 2a1 and the second abutting surface 2b1 of the oscillator 2 described below, in the outer circumferential surface 31aa of the rotor 1. The depth of the recesses V from the smooth portions W is approximately 0.5 to 2.0 μm. Furthermore, the value for the surface roughness of the outer circumferential surface 31aa of the first rotor section 31a shown in FIG. 7(a) as derived by a ten-point average roughness value RZJIS is approximately 1.6 μm. The same applies also to the outer circumferential surface 31ba of the second rotor section 31b.

The outer circumferential surface 31aa of the first rotor section 31a and the outer circumferential surface 31ba of the second rotor section 31b constitute opposing surfaces.

Due to the fact that the lubricating member 10 contacts the outer circumferential surface 31aa and the outer circumferential surface 31ba having recesses V formed over the whole surface thereof, the oil which is used as a liquid lubricant is drawn into and held in the recesses V by capillary action. Furthermore, since the ultrasonic vibrations are transmitted to the first rotor section 31a and the second rotor section 31b via the oscillator 2, then the drawing of the oil into the recesses V is promoted further. Due to the rotation of the first rotor section 31a and the second rotor section 31b, the recesses V in which the oil is held on the outer circumferential surfaces 31aa and 31ba make contact with the first abutting surface 2a1 and the second abutting surface 2b1 of the oscillator 2. As a result of this, the oil held in the recesses V of the outer circumferential surfaces 31aa and 31ba is released, and oil is supplied to the whole of the contact regions between the outer circumferential surfaces 31aa and 31ba, and the first abutting surface 2a1 and the second abutting surface 2b1.

Therefore, the contact regions between the first rotor section 31a and the second rotor section 31b, and the oscillator 2, are lubricated with oil. Consequently, the occurrence of wear between the oscillator 2, and the first rotor section 31a and the second rotor section 31b which rotate while being pushed against the oscillator 2 by the pre-load member 8, is suppressed. In other words, the lifespan of the oscillation actuator is increased.

In particular, during start-up, since oil is supplied instantaneously by the ultrasonic vibrations in a state where the oil film is liable to be eliminated due to the pre-load, then the occurrence of wear during start-up is suppressed. In other words, the start-up of the oscillation actuator is smooth.

Next, the method of processing the outer circumferential surfaces 31aa and 31ba of the first rotor section 31a and the second rotor section 31b will be described with reference to FIGS. 7(a) to 7(c). Here, FIG. 7(h) is a partial enlarged diagram showing a roughness curve of the outer circumferential surface 31aa or 31ba of the rotor 31, before carrying out a surface grinding process, and also depicting a schematic view of the surface state thereof. Furthermore, FIG. 7(c) is a diagram showing a roughness curve of the outer circumferential surfaces 31aa or 31ba in a state of increased surface smoothness after carrying out sufficient surface grinding of the outer circumferential surfaces 31aa or 31ab of the rotor 31.

First, the first rotor section 31a and the second rotor section 31b are shaped to a prescribed shape in a ceramic material and calcined, and are processed roughly into a cylindrical shape by a commonly known method. In this roughly processed state, whole of the outer circumferential surfaces 31aa and 31ba of the rotor 31 have an undulating layer U consisting of sharply projecting projections W′ and hole-like sunken recesses V (see FIG. 7(b)). The value of the surface roughness of the outer circumferential surfaces 31aa and 31ba in the roughly processed state as derived by a ten-point average roughness value RZJIS is approximately 3.2 μm. If the rotor 31 were used in the oscillation actuator 101 in a state where only this rough processing has been carried out, then the sharply projecting projections W′ of the outer circumferential surfaces 31aa and 31ba would cut into and damage the first abutting surface 2a1 and the second abutting surface 2b1 of the oscillator 2, and hence there would be a risk of promoting wear of the oscillator 2. On the other hand, if the outer circumferential surfaces 31aa and 31ba of the rotor 31 are ground sufficiently until the surface roughness becomes RZJIS=0.8 μm approximately as shown in FIG. 7(c), then the smooth portions W become the dominant feature on this surface, the number of recesses V becomes smaller, and the depth of the remaining recesses V becomes shallower. Consequently, if the rotor 31 in a state of high surface smoothness is used in the oscillation actuator 103, then there are virtually no recesses V for drawing in and holding oil in the outer circumferential surfaces 31aa and 31ba of the rotor 31. Therefore, the oil supplied when contact is made with the lubricating member 10 cannot be held sufficiently on the outer circumferential surfaces 31aa and 31ba of the rotor 31. Accordingly, it becomes impossible to supply oil efficiently to the first abutting surface 2a1 and the second abutting surface 2b1 of the oscillator 2.

In the present embodiment, surface grinding of the outer circumferential surfaces 31aa and 31ba of the rotor 31 is carried out by adjusting the grinding time and the amount of grinding agent, and the like, in such a manner that both smooth portions W and recesses V are present in the outer circumferential surfaces 31aa and 31ba of the rotor 31. For example, FIG. 7(a) shows a surface state of the outer circumferential surfaces 31aa and 31ba when grinding has been carried out until reaching a surface roughness of RSJIS=1.6 μm approximately, on a rotor 1 having outer circumferential surfaces 31aa and 31ba having a surface roughness of RZJIS=3.2 μm approximately after carrying out rough processing only. In the outer circumferential surfaces 31aa and 31ba of the rotor 31 in FIG. 7(a), the recesses V which were present in the outer circumferential surfaces 31a and 31ba in the roughly processed state are left remaining, and the projections W′ which were present in large number on the outer circumferential surfaces 31aa and 31ba in the roughly processed state are cut off to form smooth portions W. In other words, the outer circumferential surfaces 31aa and 31ba of the rotor 31 are ground to a state where both smooth portions W and recesses V coexist. Consequently, if the rotor 31 in this state is used in the oscillation actuator 103, since the smooth portions W on the outer circumferential surface 31aa and 31ba of the rotor 31 make contact with the oscillator 2, then no damage is caused to the first abutting surface 2a1 and the second abutting surface 2b1 of the oscillator 2. Moreover, since a plurality of fine recesses V remain in the outer circumferential surfaces 31aa and 31ba of the rotor 31, then it is possible to hold the oil supplied upon making contact with the lubricating member 10, in the recesses V of the outer circumferential surfaces 31aa and 31ba.

As described above, since a plurality of recesses V which are fine holes or grooves are formed in the outer circumferential surfaces 31aa and 31ba of the first rotor section 31a and the second rotor section 31b, then the oil supplied from the lubricating member 10 is held in the respective recesses V. Therefore, as the first rotor section 31a and the second rotor section 31b rotate, the portions holding the oil on the outer circumferential surfaces 31aa and 31ba contact the first abutting surface 2a1 and the second abutting surface 2b1 of the oscillator 2, and the oil is released and supplied to the first abutting surface 2a1 and the second abutting surface 2b1. Consequently, appropriate lubrication is provided in the contact regions between the first abutting surface 2a1 and the second abutting surface 2b1 of the oscillator 2, and the outer circumferential surfaces 31aa and 31ba of the rotor 1, and the occurrence of wear can be suppressed.

Moreover, the oscillation actuator 103 is configured so as to satisfy the conditions (1) to (3) given in the embodiment, and therefore it is possible to simultaneously achieve both improved durability and increased torque, similarly to the first and second embodiments.

### Fourth Embodiment

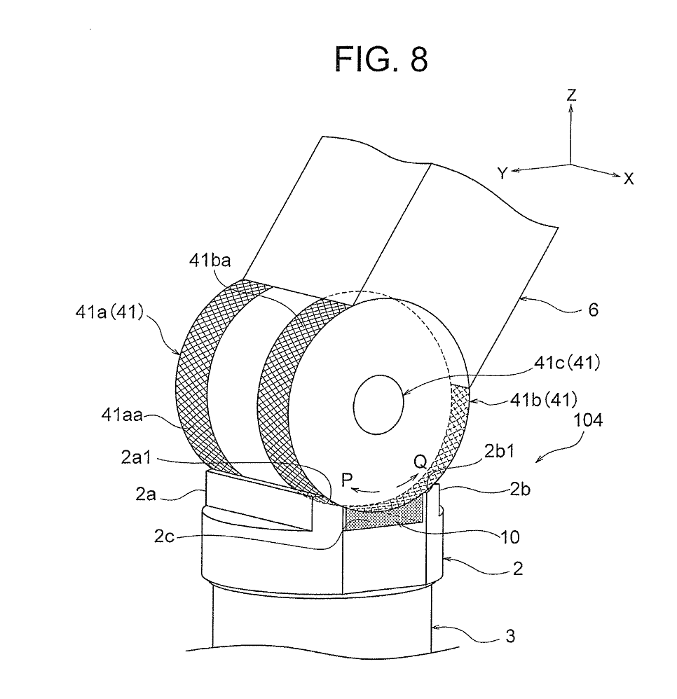

An oscillation actuator 104 relating to a fourth embodiment of the invention will now be described with reference to FIG. 8 to FIG. 10. The oscillation actuator 104 uses a rotor 41 in which the shape of the outer circumferential surfaces 1aa and 1ba of the rotor 1 in the oscillation actuator 101 of the first embodiment is changed. The rotor 41 is pressured against the oscillator 2 by the pre-load member 8, and a contact pressure of 30 MPa acts between the rotor 41 and the oscillator 2. In other words, the oscillation actuator 104 is configured in such a manner that the contact pressure acting between the rotor 41 and the oscillator 2 satisfies a condition similar to condition (1) given in the first embodiment.

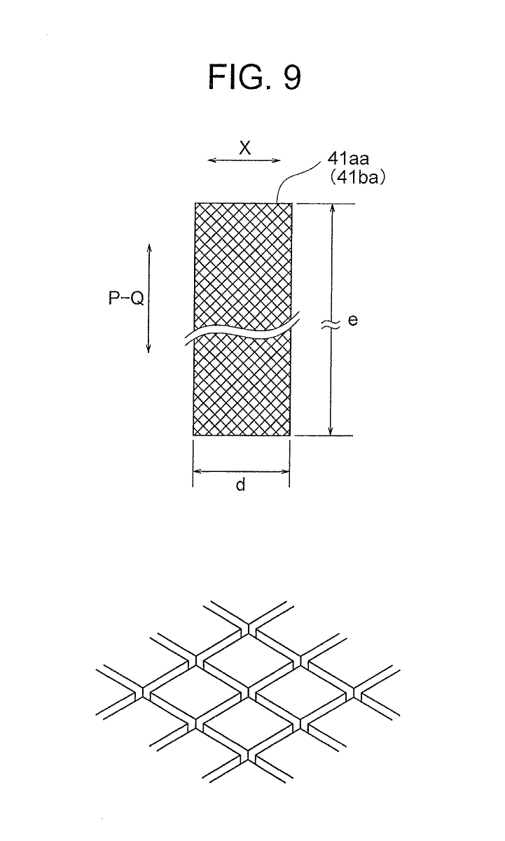

FIG. 8 is an overall diagram of the oscillation actuator 104. Furthermore, FIG. 8 is a diagram showing the outer circumferential surface 41aa of the first rotor section 41a or the outer circumferential surface 41ba of the second rotor section 41b as expanded to a flat shape, and a partial enlarged diagram of the outer circumferential surface 41aa or 41ba. As shown by the expanded diagram in FIG. 9, the outer circumferential surfaces 41aa or 41ba can be represented by a rectangular shape in which the shorter edges are the rotor width d and the longer edges are the sliding length e. Here, the sliding length e means the length in the P-Q direction of the range of the outer circumferential surfaces 41aa and 41ba which contact the first abutting surface 2a1 and the second abutting surface 2b1, and the lubricating member 10. In the present embodiment, the first rotor section 41a and the second rotor section 41b slide against the first abutting surface 2a1 and the second abutting surface 2b1 on the side of the oscillator 2, apart from the portion where the arm member 6 is installed, and therefore the sliding length e is the circumferential length of the first rotor section 41a and the second rotor section 41b, minus the length of the attaching portion of the arm member 6.

The outer circumferential surface 41aa of the first rotor section 41a and the outer circumferential surface 41ba of the second rotor section 41b constitute opposing surfaces.

As shown by the enlarged diagram in FIG. 9, a plurality of straight lines having two groove directions which intersect obliquely with the direction of rotation P-Q of the rotor 41 are processed as grooves in the outer circumferential surfaces 41aa and 41ba. Here, the groove directions are the directions in which the straight grooves are traced on the outer circumferential surfaces 41aa and 41ba. These grooves are formed in a lattice-shaped pattern overall, as shown in FIG. 8 and FIG. 9. The depth of the grooves is approximately 2 to 3 μm.

The method of processing the outer circumferential surfaces 41aa and 41ba in the oscillation actuator 104 relating to the fourth embodiment will now be described.

Firstly, the outer circumferential surfaces 41aa and 41ba of the first rotor section 41a and the second rotor section 41b are ground, or similarly worked, to achieve a state in which there are virtually no undulations in the surface and the surface has high smoothness, as shown in FIG. 7(c). Next, grooves which are recesses are formed by laser processing, for example, in the outer circumferential surfaces 41aa and 41ba of which the surface smoothness is raised. In the present embodiment, the grooves which are recesses are formed in a lattice shape in the outer circumferential surface of the rotor. The laser processing permits fine adjustment in respect of the width and depth of the grooves.

In this way, by carrying out groove processing on the outer circumferential surfaces 41aa and 41ba of the first rotor section 41a and the second rotor section 41b, when the outer circumferential surfaces 41aa and 41ba make contact with the lubricating member 10 due to the rotation of the rotor 41, then the oil of the lubricating member 10 is drawn into and held in the grooves in the outer circumferential surfaces 41aa and 41ba due to capillary action. The grooves formed in the outer circumferential surfaces 41a and 41ba of the rotor 41 also function as an oil reservoir, and enable a large amount of oil to be held on the outer circumferential surfaces 41aa and 41ba of the rotor 41. Due to the rotation of the rotor 41, the portions of the outer circumferential surfaces 41aa and 41ba holding oil make contact with the first abutting surface 2a1 and the second abutting surface 2b1 of the oscillator 2. As a result of this, the oil held on the outer circumferential surfaces 41aa and 41ba is released and supplied to the whole of the contact regions between the outer circumferential surfaces 41aa and 41ba and the first abutting surface 2a1 and the second abutting surface 2b1. Consequently, it is possible to supply sufficient oil between the outer circumferential surfaces 41aa and 41ba and the first abutting surface 2a1 and the second abutting surface 2b1, and the occurrence of wear can be suppressed more efficiently.

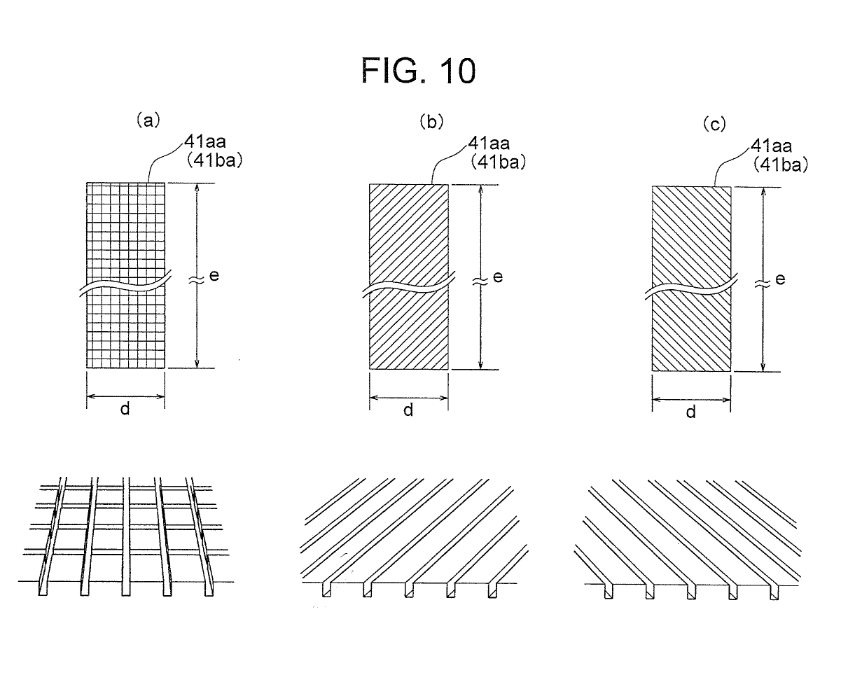

The pattern of the grooves provided on the outer circumferential surfaces 41aa and 41ba is not limited to the present embodiment. More specifically, as shown in FIG. 10(a), the grooves may be formed in a lattice-shaped pattern overall, by longitudinal and lateral intersection of grooves having a plurality of groove directions which are traced in parallel to the direction of rotation P-Q of the rotor and the x axis direction. Furthermore, as shown in FIG. 10(b) or FIG. 10(c), it is also possible to adopt a groove pattern having an oblique line pattern overall, by parallel equidistant arrangement of grooves having the same groove direction which intersect obliquely with the direction of rotation P-Q of the rotor and the x axis direction. Furthermore, the number of grooves processed in the outer circumferential surfaces 41aa and 41ba is not limited to a plural number and may be a single groove.

Furthermore, fine holes may be formed in the whole of the outer circumferential surfaces 41aa and 41ba.

Moreover, it is also possible to process the grooves only in a portion of the outer circumferential surfaces 41aa and 41ba, provided that they are positioned in a range where the outer circumferential surfaces 41aa and 41ba make contact with the first abutting surface 2a1 and the second abutting surface 2b1.

Furthermore, the oscillation actuator 104 is configured so as to satisfy the conditions (1) to (3) given in the first embodiment, and therefore it is possible to achieve both improved durability and increased torque similarly to the first to third embodiments.

### Fifth Embodiment

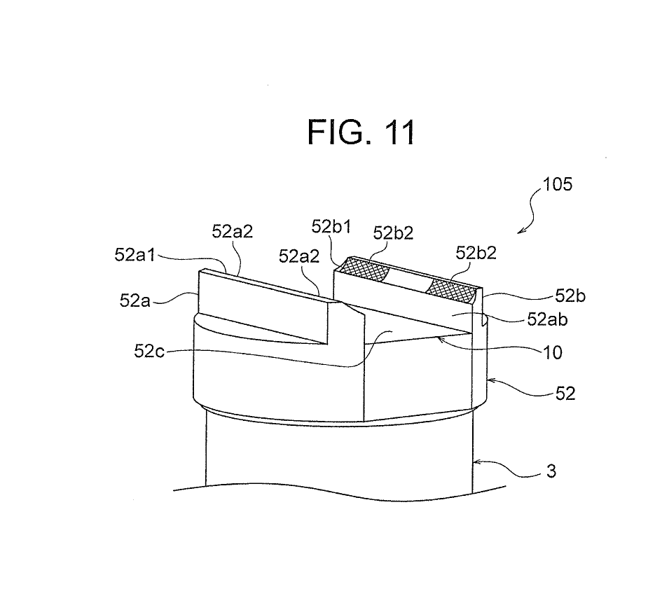

Next, the oscillation actuator 105 relating to the fifth embodiment of this invention will be described with reference to FIG. 11 to FIG. 14. The oscillation actuator 105 uses an oscillator 52 in which the shape of the first abutting surface 2a1 and the second abutting surface 2b1 of the oscillator 2 in the oscillation actuator 101 according to the first embodiment is changed. The rotor 1 is pressured against the oscillator 52 by a pre-load member 8, and a contact pressure of 30 MPa acts between the rotor 1 and the oscillator 52. More specifically, the oscillation actuator 105 is configured in such a manner that the contact pressure acting between the rotor 1 and the oscillator 52 satisfies a condition similar to condition (1) given in the first embodiment.

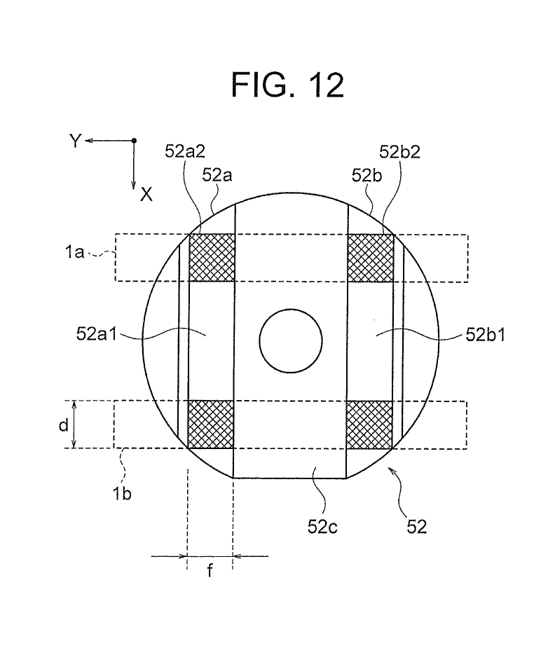

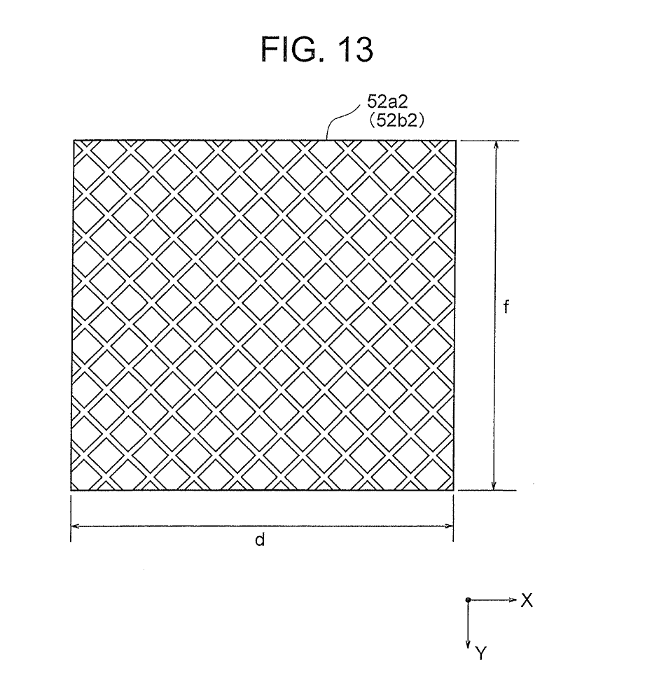

FIG. 11 is a perspective diagram showing an oscillator 52 relating to the oscillation actuator 105. As shown in FIG. 11, the oscillator 52 has contact surfaces 52a2 and 52b2 in a portion of the first abutting surface 52a1 and the second abutting surface 52b1. The contact surfaces 52a2 and 52b2 are portions which contact the outer circumferential surfaces 1aa and 1ba of the rotor 1, and are each provided as a pair on the first abutting surface 52a1 and the second abutting surface 52b1 so as to correspond to the first rotor section 1a and the second rotor section 1b. Furthermore, FIG. 12 is a plan diagram showing the oscillator 52 as viewed from above, and FIG. 13 is a schematic drawing of a contact surface 52a2 or 52b2. In other words, the contact surfaces 52a2 and 52b2 are the regions of the first abutting surface 52a1 and the second abutting surface 52b1 which are contacted by the outer circumferential surfaces 1aa and 1ba, and have a square shape as shown in FIG. 12 and FIG. 13. Here, one edge of the contact surfaces 52a2 and 52b2 is the width of the outer circumferential surface 1aa and 1ba of the rotor 1 (the rotor width d). Furthermore, the other edge is the length in the P-Q direction of the first abutting surface 2a1 and the second abutting surface 2b1 (the cylindrical width f).

A plurality of straight line-shaped grooves are processed in directions intersecting obliquely with the x axis direction and the y axis direction on the contact surfaces 52a2 and 52b2. These grooves are processed to form a lattice-shaped pattern over the whole surface, as shown in FIG. 11 to FIG. 14. The depth of the grooves is approximately 2 to 3 μm. Laser processing can be used to form the grooves, similarly to the processing of the outer circumferential surfaces 41aa and 41ba of the oscillation actuator 104. The laser processing permits fine adjustment in respect of the width and depth of the grooves.

As described above, oil is supplied directly from the lubricating member 10 to the contact surfaces 52a2 and 52b2 of the oscillator 52, in accordance with the pump effects due to surface tension and the characteristics of the liquid that collects at the antinode of the ultrasonic vibration. Furthermore, the oil held in the undulations on the outer circumferential surface 1aa and 1ba of the rotor 1 is conveyed by the rotation of the rotor 1 and is supplied to the contact surfaces 52a2 and 52b2. By forming grooves in the contact surfaces 52a2 and 52b2 of the oscillator 52, this oil supplied to the oscillator 52 is held in the grooves. Consequently, it is possible to suppress the occurrence of wear between the outer circumferential surfaces 1aa and 1ba of the rotor 1 and the first abutting surface 52a1 and the second abutting surface 52b1 of the oscillator 52.

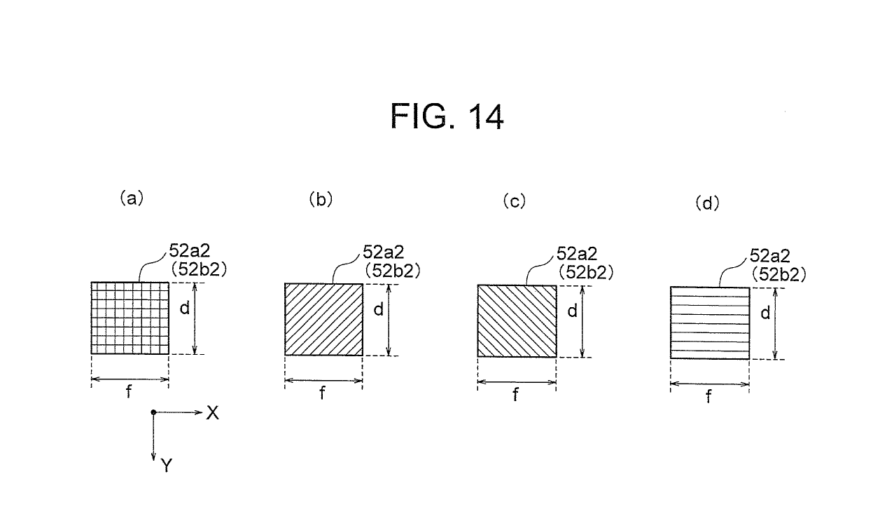

The pattern of the grooves provided on the contact surfaces 52a2 and 52b2 is not limited to that in the present embodiment. More specifically, as shown in FIG. 14(a), it is also possible to form a groove pattern in a lattice-shaped arrangement overall, by longitudinal and lateral intersection of grooves having a plurality of groove directions traced in parallel with the x axis direction and the y axis direction. Furthermore, as shown in FIG. 14(b) or 14(c), it is also possible to form a groove pattern in an oblique line arrangement overall, by parallel equidistant arrangement of a plurality of grooves in a single groove direction which is oblique to the x axis direction and the y axis direction. Moreover, as shown in FIG. 14(d), it is also possible to form an equidistant arrangement of a plurality of grooves having a single groove direction which is parallel to the x axis direction. Furthermore, the number of grooves provided on the contact surfaces 52a2 and 52b2 is not limited to a plurality of grooves and may also be a single groove.

Moreover, fine holes may also be formed over the whole of the contact surfaces 52a2 and 52b2.

Furthermore, grooves may be formed not only on the contact surfaces 52a2 and 52b2, but also over the whole of the first abutting surface 52a1 and the second abutting surface 52b1.

Moreover, it is also possible to use an oscillation actuator which combines the oscillator 52 relating to the fifth embodiment and the rotor 41 relating to the fourth embodiment, as an oscillation actuator according to a further embodiment.

Furthermore, the oscillation actuator 105 is configured so as to satisfy conditions (1) to (3) given in the first embodiment, and therefore it is possible to achieve both improved durability and increased torque, similarly to the first to fourth embodiments.

### Sixth Embodiment

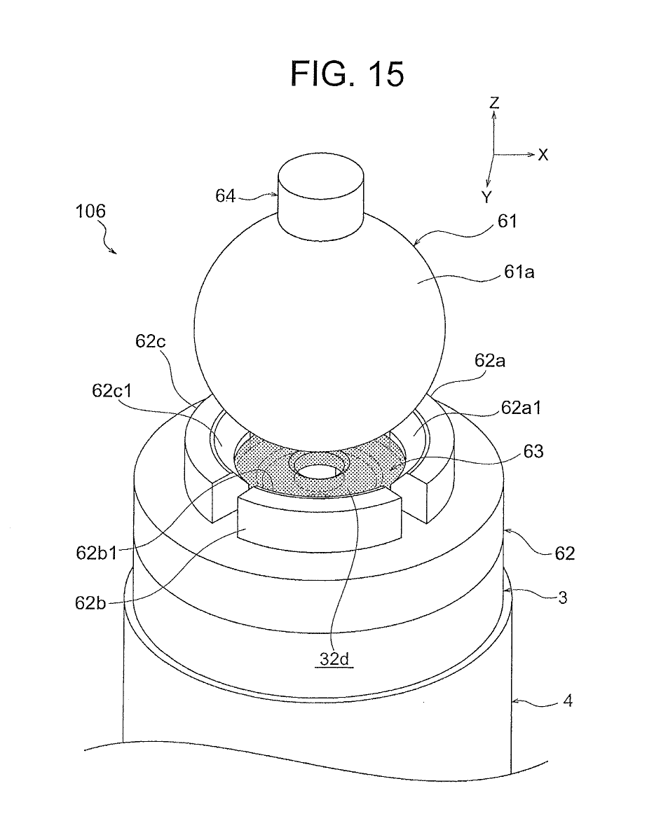

Moreover, an oscillation actuator relating to the sixth embodiment will be described with reference to FIG. 15. The oscillation actuator 106 relating to this sixth embodiment is composed so as to use a spherical rotor as a moving element, whereas the oscillation actuators 101 to 105 relating to the first to fifth embodiments use a substantially cylindrical rotor as the moving element.

As shown in FIG. 15, the oscillation actuator 106 is provided with a rotor 61, which is a spherical moving element, and an oscillator 62, which is an oscillator with which the rotor 61 makes contact. Three projecting claw sections 62a to 62c formed in a substantially cylindrical shape are provided on the ends of the oscillator 62 which is positioned on the side of the rotor 61, so as to project towards the rotor 61, and spherical abutting surfaces 62a1 to 62c1 corresponding to the outer circumferential surface 61a of the rotor 61 are formed respectively on these projecting claw sections 62a to 62c. Furthermore, a substantially cylindrical supply body 63 made from the same resin material as the supply body 10 of the first embodiment is provided inside a recess 62d formed inside the projecting claw sections 62a to 62c, and this supply body 63 is impregnated with a fluorine-based oil having a viscosity at 40° C. of VG 400 according to the ISO viscosity classification. Moreover, a pre-load unit 64 is arranged above the rotor 61, and the rotor 61 is pressured against the oscillator 62 by this pre-load unit 64.

The outer circumferential surface 61a of the rotor 61 constitutes an opposing surface.

Here, FIG. 15 shows a state where the rotor 61 and the oscillator 62 are separated, in order to depict the recess 62d of the oscillator 62, and the supply body 63, and in the actual oscillation actuator 106, the outer circumferential surface 61a of the rotor 61 and the abutting surfaces 62a1 to 62c1 of the projecting claw sections 62a to 62c of the oscillator 62 make surface contact. Furthermore, the pre-load unit 64 causes a contact pressure of 30 MPa to act between the rotor 61 and the oscillator 62, in other words, between the outer circumferential surface 61a of the rotor 61 and the abutting surfaces 62a1 to 62c1 of the projecting claw sections 62a to 62c of the oscillator 62. In other words, in this sixth embodiment, an oscillation actuator 106 in which the ultrasonic vibrations generated in an oscillator 62 by a piezoelectric element 3 are used to rotate a rotor 61 in a universal free, is composed so as to satisfy conditions (1) to (3) given in the first embodiment. Furthermore, the remainder of the composition apart from that described above is similar to that of the first embodiment.

As described above, even if the oscillation actuator 106 is composed so as to drive a spherical rotor 61, it is possible to achieve both improved durability and increased torque, similarly to the first embodiment.

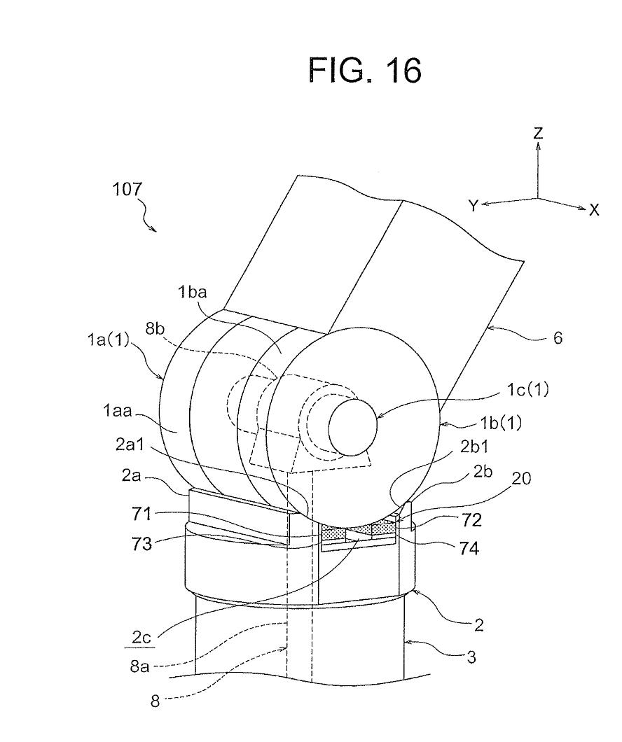

In the first embodiment, the supply body 10, which is the lubricant supply unit (see FIG. 1), is formed as a single member arranged inside the recess 2c of the oscillator 2, but the supply body 10 is not limited to being a single member. It is also possible to adopt a configuration in which two supply bodies 71, 72 are arranged inside the recess 2c of the oscillator 2, as in the oscillation actuator 107 shown in FIG. 16, for example, since it is sufficient to be able to supply oil between the rotor 1 and the oscillator 2. In this case, the supply body 71 contacts the first rotor section 1a and the second rotor section 1b of the rotor 1 and the first projecting claw section 2a of the oscillator 2, and the supply body 72 contacts the first rotor section 1a and the second rotor section 1b of the rotor 1 and the second projecting claw section 2b of the oscillator 2. Furthermore, since these supply bodies 71, 72 are held inside the recess 2c, then it is possible to provide flat plate-shaped supporting members 73, 74 made from metal, or the like, in the bottom section of the recess 2c, and to fix the supply bodies 71, 72 respectively onto the supporting members 73, 74.

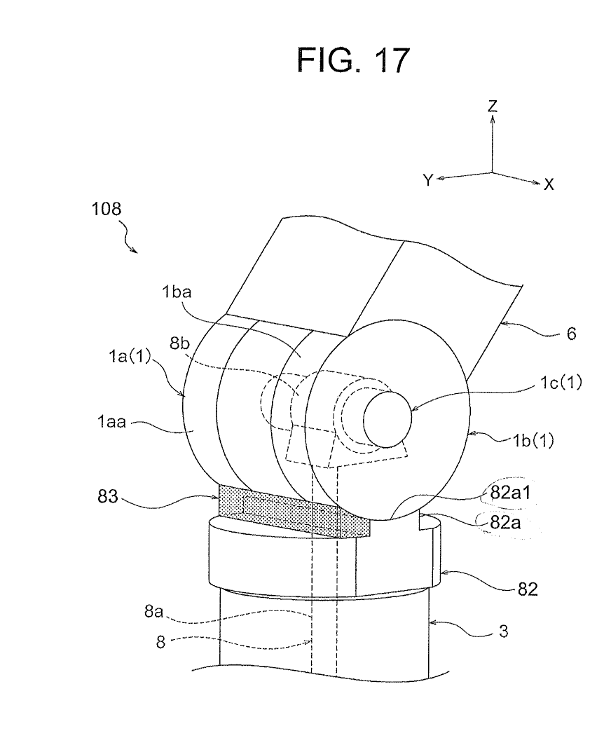

Moreover, in the oscillation actuator 101 in the first embodiment (see FIG. 1), a pair of projecting claw sections 2a, 2b is provided on the oscillator 2, and a supply body 10 is arranged in the recess 2c therebetween, but the configuration is not limited to one in which the supply body is arranged between a plurality of projecting claw sections. For example, it is also possible to adopt a configuration in which the oscillator 82 has a single projecting claw section 82a of which the central portion extends in a straight line shape, as in the oscillation actuator 108 shown in FIG. 17. In this case, the first rotor section 1a and the second rotor section 1b of the rotor 1 and the abutting surface 82a1 formed on the top end section of the projecting claw section 82a make surface contact. Furthermore, the supply body 83 which is impregnated with oil is arranged on one or both sides of the projecting claw section 82a, and the supply body 83 supplies oil by making contact with the first rotor section 1a and the second rotor section 1b of the rotor 1.

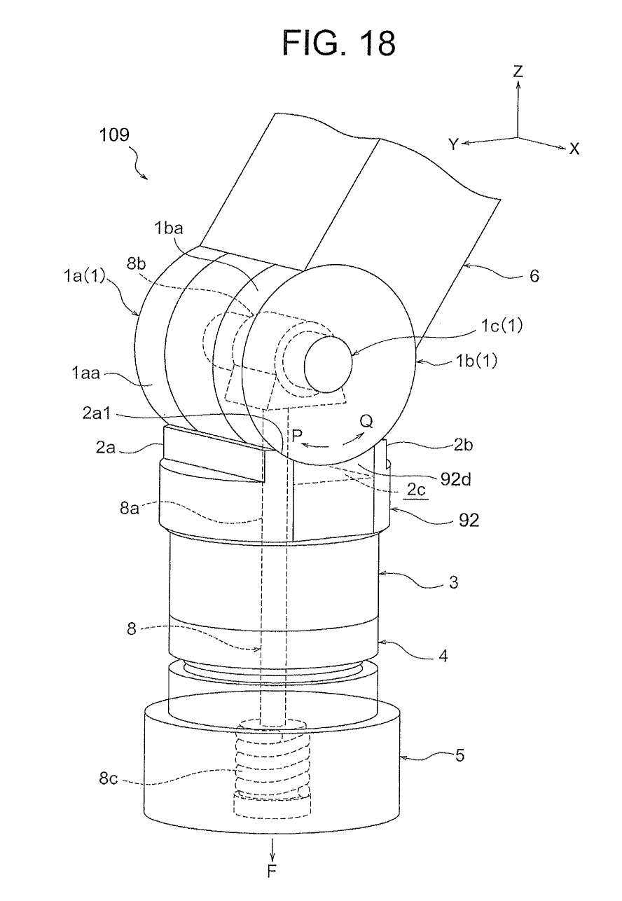

In the first to sixth embodiments, a supply body made from a porous resin material was used for the lubricant supply unit for supplying oil between the rotor and the vibrating agent, but the invention is not limited to using a supply body of this kind. For example, it is also possible to adopt a composition in which wall sections 92d are provided to enclose the space between the first projecting claw section 2a and the second projecting claw section 2b, in other words, to close off both ends of the recess 2c of the oscillator 2 in the X axis direction, as in the oscillator 92 of the oscillation actuator 109 shown in FIG. 18, and the rotor 1 is immersed in oil collected inside the wall sections 92d. In this case also, it is possible to supply oil directly to the outer circumferential surface of the rotor 1 without using a supply body, and therefore the number of components can be reduced and costs can be lowered. The lubricant supply unit in this case is the space where the oil is collected which is surrounded by the first projecting claw section 2a, the second projecting claw section 2b and the pair of wall sections 92d.

### Seventh Embodiment

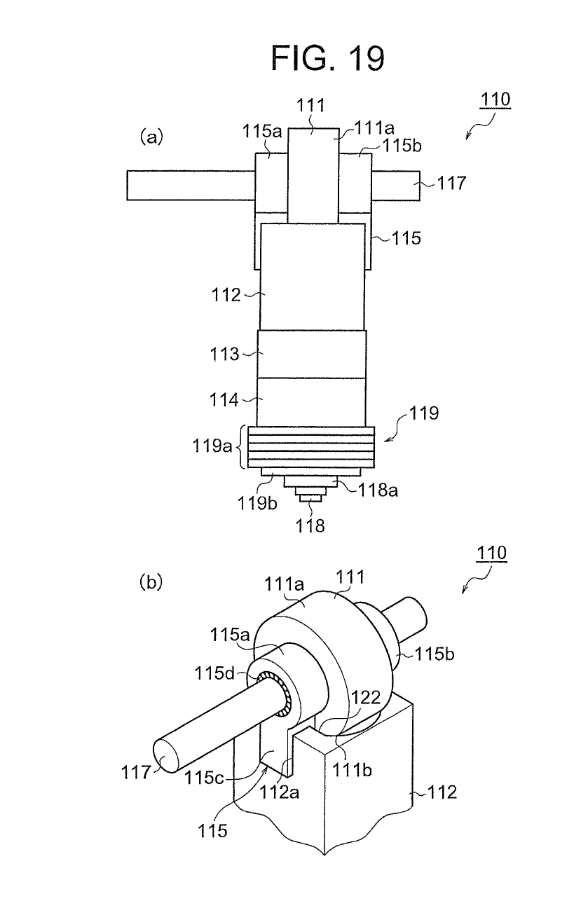

Next, the oscillation actuator 110 relating to the seventh embodiment of this invention is described with reference to FIG. 19 to FIG. 22. The oscillation actuator 110 differs from the oscillation actuator 101 which is provided with two rotors, in that only one rotor is provided.

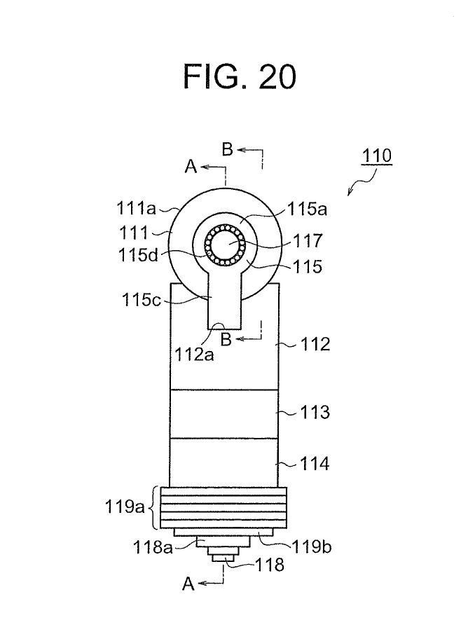

As shown in FIG. 19(a) and FIG. 20, a piezoelectric element 113 is arranged as an oscillation unit in the oscillation actuator 110. The piezoelectric element 113 has a cylindrical shape and has a structure in which a plurality of circular plate-shaped piezoelectric element plates are laminated together. The piezoelectric element 113 is connected electrically to a drive circuit (not illustrated), and generates ultrasonic vibrations due to an AC voltage being applied from a drive circuit.

A stator 112 (oscillator) having a block shape is fixed in a state of contact with the piezoelectric element 113 on one end surface of the piezoelectric element 113. A base block 114 having a cylindrical shape is fixed to the other end surface of the piezoelectric element 113 (the surface on the opposite side to the stator 112).

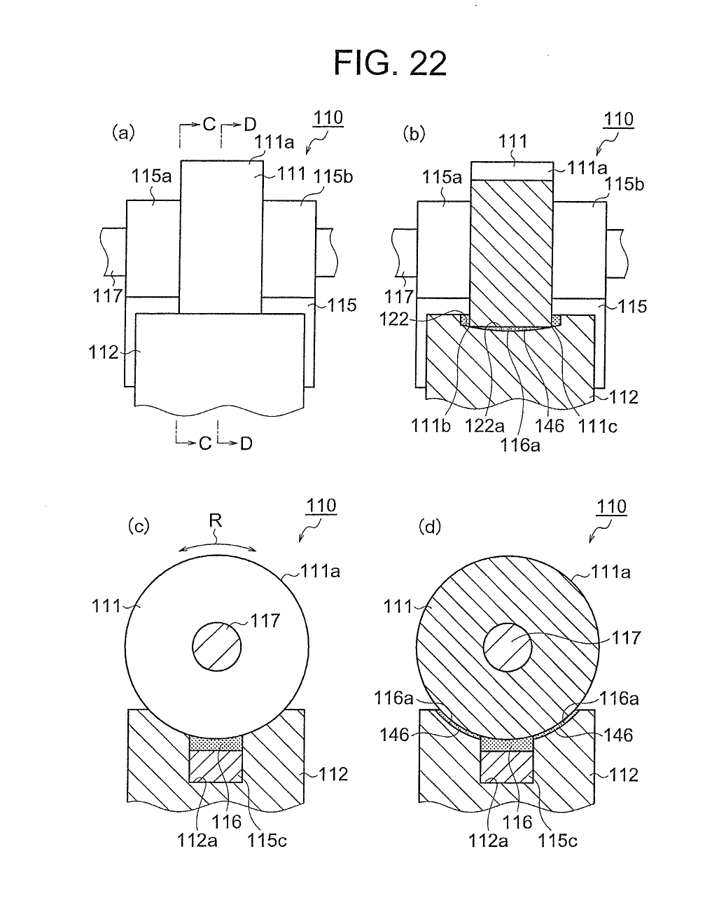

As shown in FIG. 22(b), a mounting section 122 is provided in a recessed on the surface of the stator 112 on the opposite side to the piezoelectric element 113, and furthermore, a rotor 111 (rotating element) having a cylindrical shape is contacted by and supported on the mounting section 122. The rotor 111 is arranged in such a manner that the outer circumferential surface 111a thereof contacts the mounting section 122 of the stator 112. Gaps are formed between the two side faces of the rotor 111 (the two surfaces positioned in the thickness direction of the rotor 111), and the side faces of the mounting section 122 which oppose the two side faces of the rotor 111. The stator 112 is made from stainless steel, for example, and furthermore, the rotor 111 is made from ceramic or alumina, for example.

The rotor 111 constitutes a moving element and the outer circumferential surface 111a thereof constitutes an opposing surface.

As shown in FIG. 19B, the outer circumferential surface 111a of the rotor 111 is formed in a flat surface shape in the thickness direction of the rotor 111. A rotating shaft 117 is passed through the rotor 111. The rotor 111 is driven to rotate in an integrated with the rotating shaft 117 above the rotating shaft 117. A groove section 112a is formed in the surface of the stator 112 on the opposite side to the piezoelectric element 113. The groove section 112a extends in the same direction as the direction of extension of the rotating shaft 117.

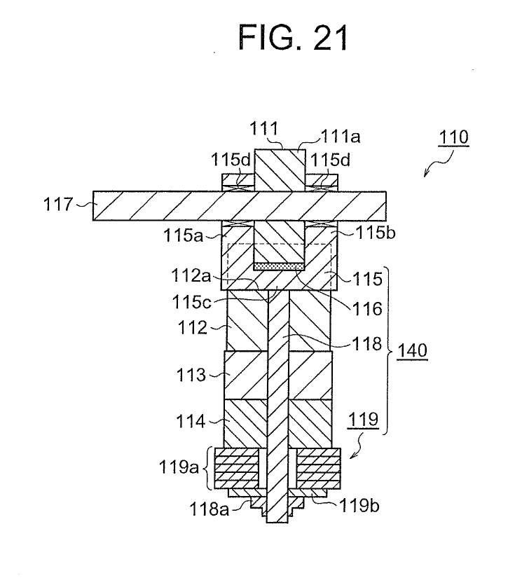

As shown in FIG. 21, the rotor 111 is pressed by a pre-load unit 140 to make pressured contact with the mounting section 122 of the stator 112. The pre-load unit 140 is composed of an attaching section 115, a bar-shaped axle section 118 which is coupled to the attaching section 115, and an urging section 119 which impels the axle section 118. The attaching section 115 is formed by a pair of attaching pieces 115a, 115b which are supported on the rotating shaft 117 via bearings 115d and surround the circumference of the rotating shaft 117, and a joining section 115c which joins the pair of attaching pieces 115a, 115b together. The joining section 115c passes via the groove section 112a to join together the base ends of the pair of the attaching pieces 115a, 115b on the side adjacent to the piezoelectric element 113.

A contact pressure of 30 MPa acts between the rotor 111 and the mounting section 122 of the stator 112. In other words, the oscillation actuator 110 is composed in such a manner that the contact pressure acting between the rotor 111 and the stator 112 satisfies a similar condition to condition (1) specified in the first embodiment.

One end of the axle section 118 is coupled to the joining section 115c, and the other end thereof passes through the stator 112, the piezoelectric element 113, and the base block 114, and projects from the base block 114. A connecting member 118a having a cylindrical shape is affixed to the other end of the axle section 118. A plurality of circular ring-shaped leaf springs 119a are affixed in a layered state on the surface of the base block 114 opposite to the side adjacent to the piezoelectric element 113. The axle section 118 is inserted through the inside of the leaf springs 119a. A circular plate-shaped spring receiving member 119b is coupled to the leaf spring 119a which is positioned furthest to the side opposite to the base block 114, of the plurality of leaf springs 119a. The spring receiving member 119b is coupled to the connecting member 118a. The axle section 118 is urged to the other end side by the leaf springs 119a, via the spring receiving member 119b and the connecting member 118a. As a result of this, the rotor 111 is pressed against the stator 112 via the attaching section 115 and the rotating shaft 117. Therefore, in the present embodiment, an urging section 119 is composed of the leaf springs 119a and the spring receiving member 119b.

As shown in FIG. 22A, a supply body 116 acting as a lubricant supply unit is disposed in the groove section 112a of the stator 112, between the rotor 111 and the joining section 115c. More specifically, the supply body 116 is disposed in the vicinity of the mounting section 122 of the stator 112. The supply body 116 is a porous resin member having flexibility which is impregnated with oil 116a that acts as a lubricant, such as oil or grease. The supply body 116 contacts and is pressed and squashed by the rotor 111 which is pressed against the mounting section 122 of the stator 112, in such a manner that the oil 116a seeps out from the supply body 116.

The oil 116a is a fluorine-based oil having a kinetic viscosity at 40° C. of VG 400 according to the ISO viscosity classifications, and is composed so as to satisfy the conditions (2) and (3) specified in the first embodiment.

As shown in FIG. 22(b), a curved surface 122a which is curved in an arc shape is formed on the mounting section 122 of the stator 112, apart from the portion corresponding to the groove section 112a, so as to be recessed towards the side opposite to the rotor 111 in the thickness direction of the rotor 111. When the contact region between the stator 112 and the rotor 111 is viewed in the radial direction of the rotor 111, both edge sections 111b and 111c of the outer circumferential surface 111a of the rotor 111 which are positioned on both ends of the rotor 111 in the thickness direction of the rotor 111 make point contact with the curved surface 122a of the stator 112. Consequently, in the present embodiment, point contact portions where the stator 112 and the rotor 111 make point contact in the thickness direction of the rotor 111 are provided in the region of opposition between the mounting section 122 of the stator 112 and the outer circumferential surface 111a of the rotor 111. In the present embodiment, two portions are formed where the stator 112 and the rotor 111 make point contact in the thickness direction of the rotor 111.

Furthermore, as shown in FIG. 22(c), the portion of the mounting section 122 of the stator 112 which opposes the rotor 111 is curved so as to follow the direction of rotation of the rotor 111 (the direction indicated by arrow R in FIG. 22(c)). The mounting section 122 of the stator 112 and the outer circumferential surface 111a of the rotor 111 make linear contact in the direction of rotation of the rotor 111. Therefore, in the present embodiment, a linear contact portion is provided in the region of opposition between the mounting section 122 of the stator 112 and the outer circumferential surface 111a of the rotor 111, in which the mounting section 122 of the stator 112 and the outer circumferential surface 111a of the rotor 111 make linear contact in the direction of rotation of the rotor 111.

Furthermore, as shown in FIG. 22(d), a gap 146 is formed in the portion where the stator 112 and the rotor 111 do not make contact, in the region of opposition between the mounting section 122 of the stator 112 and the outer circumferential surface 111a of the rotor 111, and the oil 116a which has seeped out from the supply body 116 is held in this gap 146. Consequently, in the present embodiment, the gap 146 functions as a lubricant holding portion which holds the oil 116a.

Next, the action of the present embodiment will be described.

When an AC voltage is applied to the piezoelectric element 113 from the drive circuit, the piezoelectric element plates of the piezoelectric element 113 generate ultrasonic vibrations in different vibration directions. Due to the composite vibration produced by these ultrasonic vibrations being transmitted to the stator 112, an elliptical vibration is generated in the mounting section 122 of the stator 112. Due to the elliptical vibration of the mounting section 122 of the stator 112, friction occurs in the point contact portions between the curved surface 122a of the stator 112 and the outer circumferential surface 111a of the rotor 111, and due to this friction, the rotor 111 performs a rotational movement. The direction of rotation of the rotor 111 can be switched and the rotational speed thereof can be adjusted by controlling the AC voltage that is applied to the piezoelectric element 113.

Here, the curved surface 122a of the stator 112 and the outer circumferential surface 111a of the rotor 111 make point contact in the thickness direction of the rotor 111. In other words, the stator 112 and the rotor 111 do not make surface contact. Therefore, compared to a case where the stator 112 and the rotor 111 make surface contact, the contact surface area between the stator 112 and the rotor 111 becomes smaller. As a result of this, when the rotor 111 contacts the stator 112, the force applied to the stator 112 by one point on the rotor 111 becomes greater.

If an elliptical vibration occurs in the mounting section 122 of the stator 112, then a sequence of contact and non-contact is repeated in the point contact region between the curved surface 122a of the stator 112 and the outer circumferential surface 111a of the rotor 111. When the point contact region between the curved surface 122a of the stator 112 and the outer circumferential surface 111a of the rotor 111 is in a non-contact state, then oil 116a which has seeped out from the supply body 116 is supplied between the curved surface 122a of the stator 112 and the outer circumferential surface 111a of the rotor 111.

When the rotor 111 contacts the stator 112, then the oil 116a supplied between the mounting section 122 of the stator 112 and the outer circumferential surface 111a of the rotor 111 is removed. In this case, oil 116a is held in the gap 146 in the region of opposition between the mounting section 122 of the stator 112 and the outer circumferential surface 111a of the rotor 111. As a result of this, the point contact region where the stator 112 and the rotor 111 make direct contact, and a lubricant holding region where the oil 116a is held, are formed in the region of opposition between the mounting section 122 of the stator 112 and the outer circumferential surface 111a of the rotor 111. More specifically, the state of lubrication between the stator 112 and the rotor 111 assumes a borderline lubricated state. Therefore, due to the friction in the point contact region between the stator 112 and the rotor 111, the rotor 111 rotates smoothly, lubrication is maintained satisfactorily between the stator 112 and the rotor 111, by the oil 116a held in the gap 146, and wear in the contact region between the stator 112 and the rotor 111 is reduced.

From the above, since the oscillation actuator 110 is composed so as to satisfy conditions (1) to (3) specified in the first embodiment, then it is possible to achieve both improved durability and increased torque, similarly to the first to sixth embodiments.

Furthermore, the following beneficial effects are also obtained in the seventh embodiment.

(1) A point contact region where the stator 112 and the rotor 111 make contact in the thickness direction of the rotor 111, and a lubricant holding region where the oil 116a is held, are provided in the region of opposition between the mounting section 122 of the stator 112 and the outer circumferential surface 111a of the rotor 111. Therefore, compared to a case where the stator 112 and the rotor 111 make surface contact, the contact surface area between the stator 112 and the rotor 111 can be made smaller, and when the rotor 111 contacts the stator 112, the force applied to the stator 112 by one point on the rotor 111 can be made greater. Therefore, when the rotor 111 contacts the stator 112, the oil 116a supplied between the stator 112 and the rotor 111 can be readily removed, and hence appropriate contact between the stator 112 and the rotor 111 can be achieved, while maintaining a state of lubrication between the stator 112 and the rotor 111. In other words, the state of lubrication between the stator 112 and the rotor 111 can be set to a borderline lubricated state. More specifically, it is possible to form a point contact region where the stator 112 and the rotor 111 make direct contact, and a gap 146 which is a lubricant holding region where the oil 116a is held, in the region of opposition between the mounting section 122 of the stator 112 and the outer circumferential surface 111a of the rotor 111. Therefore, it is possible to rotate the rotor 111 smoothly due to the friction in the point contact region between the stator 112 and the rotor 111, as well as being able to reduce wear in the contact region between the stator 112 and the rotor 111 by maintaining good lubrication between the stator 112 and the rotor 111 by means of the oil 116a held in the gap 146.

(2) A linear contact region where the mounting section 122 of the stator 112 and the outer circumferential surface 111a of the rotor 111 make linear contact in the direction of rotation of the rotor 111 is provided in the region of opposition between the mounting section 122 of the stator 112 and the outer circumferential surface 111a of the rotor 111. Therefore, the contact surface area between the stator 112 and the rotor 111 becomes larger, compared to a case where the contact region between the stator 112 and the rotor 111 makes point contact in the direction of rotation of the rotor 111, for example, and hence the torque transmission region becomes broader and the rotor 111 can be rotated smoothly.

(3) A point contact region is formed on the mounting section 122 of the stator 112 by forming a curved surface 122a which curves with respect to the thickness direction of the rotor 111. Therefore, it is possible to readily provide a point contact region in the region of opposition between the mounting section 122 of the stator 112 and the outer circumferential surface 111a of the rotor 111, simply by changing the shape of the stator 112.

(4) A supply body 116 impregnated with oil 116a is provided in the vicinity of the mounting section 122 of the stator 112, and further so as to make contact with the outer circumferential surface 111a of the rotor 111. Therefore, it is possible to supply oil 116a smoothly to the region of opposition between the mounting section 122 of the stator 112 and the outer circumferential surface 111a of the rotor 111.

The seventh embodiment may also be modified as indicated below.

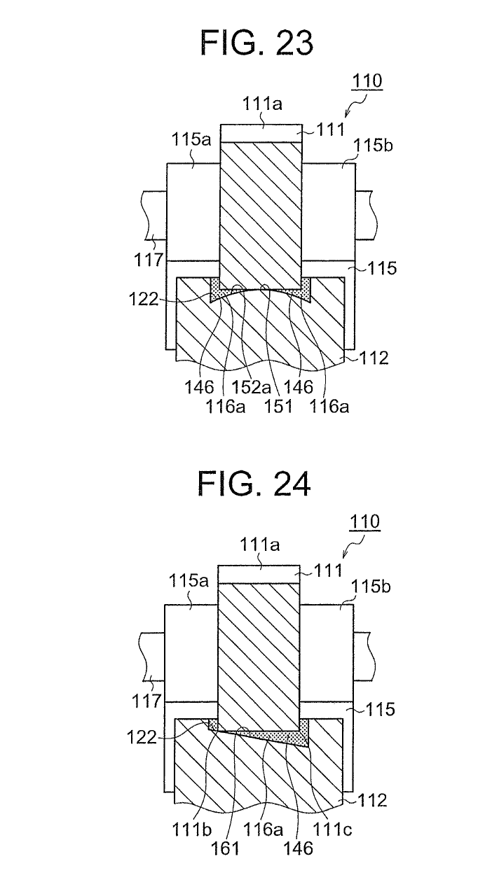

As shown in FIG. 23, it is also possible to form a curved surface 152a which is curved in an arc shape so as to swell towards the rotor 111 in the thickness direction of the rotor 111, in the portion of the mounting section 122 of the stator 112 apart from the groove section 112a. Accordingly, if the contact region between the stator 112 and the rotor 111 is viewed in the radial direction of the rotor 111, then the peak section 151 of the curved surface 152a makes point contact with the outer circumferential surface 111a of the rotor 111 in the thickness direction of the rotor 111.

As shown in FIG. 24, a tapered surface 161 which is inclined with respect to the thickness direction of the rotor 111 may be formed in the portion of the mounting section 122 of the stator 112 apart from the groove section 112a. Accordingly, if the contact region between the stator 112 and the rotor 111 is viewed in the radial direction of the rotor 111, one edge section 111b of the outer circumferential surface 111a of the rotor 111 makes point contact with respect to the tapered surface 161, in the thickness direction of the rotor 111.

Moreover, the seventh embodiment may also be changed as described below, in order that the stator 112 and the rotor 111 make point contact in the thickness direction of the rotor 111.

More specifically, the mounting section 122 of the stator 112 may be formed in a flat surface shape with respect to the thickness direction of the rotor 111, in addition to which the outer circumferential surface 111a of the rotor 111 may be curved in an arc shape so as to swell towards the stator 112 in the thickness direction of the rotor 111.

Furthermore, the mounting section 122 of the stator 112 may be formed in a flat surface shape with respect to the thickness direction of the rotor 111, in addition to which the outer circumferential surface 111a of the rotor 111 may be inclined in a downward linear shape from one edge section 111b to the other edge section 111c of the outer circumferential surface 111a or the rotor 111, in the thickness direction of the rotor 111.

Moreover, the mounting section 122 of the stator 112 may be formed in a flat surface shape with respect to the thickness direction of the rotor 111, in addition to which the outer circumferential surface 111a of the rotor 111 may be curved in an arc shape so as to be recessed towards the opposite side from the stator 112, in the thickness direction of the rotor 111.

Furthermore, the outer circumferential surface 111a of the rotor 111 may be curved in an arc shape so as to swell towards the stator 112 in the thickness direction of the rotor 111, with a different curvature to that of the curved surface 122a of the stator 112. More specifically, in this case, the curvature of the outer circumferential surface 111a of the rotor 111 becomes greater than the curvature of the curved surface of the stator 112.

In other words, even if the shape of the rotor 111 is changed as described above, it is possible to adopt a configuration in which the rotor 111 makes point contact with the stator 112 in the thickness direction of the rotor 111.

In the first to seventh embodiments, the rotors, which are moving elements, are configured as members having a substantially cylindrical shape or spherical shape, but the shape of the moving element is not limited to a cylindrical shape or spherical shape. For example, the present invention can also be applied to an oscillation actuator provided with a moving element having another shape, such as an oscillation actuator which causes a circular ring-shaped moving element to rotate about the axis direction, or a so-called linear oscillation actuator which causes a bar-shaped or column-shaped moving element to move linearly.

### EXPLANATION OF REFERENCE NUMERALS

1, 31, 41, 61, 111 rotor (moving element)
1a, 31a, 41a first rotor section (moving element)
1b, 31b, 41b second rotor section (moving element)
1c, 31c, 41c rotor shaft (moving element)
1aa, 1ba outer circumferential surface (opposing surface, moving element-side contact surface)
31aa, 31ba, 41aa, 41ba, 111a outer circumferential surface (opposing surface)
61a outer surface (opposing surface)
2, 52, 62, 82, 92 moving element
2a, 52a first projecting claw section (projecting claw section)
2a1, 52a1 first abutting surface (abutting surface)
2b, 52b second projecting claw section (projecting claw section)
2b1, 52b1 second abutting surface (abutting surface)
2a2 first contact surface (oscillator-side contact surface)
2b2 second contact surface (oscillator-side contact surface)
62a, 62b, 62c, 82a projecting claw section
62a1, 62b1, 62c1, 82a1 abutting surface
3 piezoelectric element (oscillation unit)
8, 64 pre-load member (pre-load unit)
10, 63, 71, 72, 83 supply body (lubricant supply unit)
101, 102, 103, 104, 105, 106, 107, 108, 109, 110 oscillation actuator
122 mounting section
152a curved surface
161 tapered surface
V recess
W smooth section (projection)
W′ projection

1. An oscillation actuator, comprising:
a moving element;
an oscillator capable of making contact with the moving element;
a pre-load unit which pressures and causes contact between the moving element and the oscillator;
an oscillation unit which causes the moving element to move by generating ultrasonic vibrations in the oscillator; and
a lubricant supply unit capable of supplying liquid lubricant between the moving element and the oscillator,
wherein the pre-load unit pressures and causes contact between the moving element and the oscillator in such a manner that a contact pressure in a range of 10 MPa to 100 MPa acts between the moving element and the oscillator,
kinetic viscosity at 40° C. of the liquid lubricant is in a range of VG 200 to VG 1200 according to the ISO viscosity classification, and
surface tension of the liquid lubricant is in a range of 15 mN/m to 25 mN/m.

2. The oscillation actuator according to claim 1, wherein the lubricant supply unit is a supply body which is impregnated with the liquid lubricant and is provided so as to be able to contact at least one of the moving element and the oscillator.

3. The oscillation actuator according to claim 1, wherein the contact pressure is in a range of 30 MPa to 60 MPa.

4. The oscillation actuator according to claim 1, wherein the kinetic viscosity at 40° C. of the liquid lubricant is in a range of VG 400 to VG 800 according to the ISO viscosity classification.

5. The oscillation actuator according to claim 1, wherein the lubricant supply unit supplies a grease having the liquid lubricant as a base oil, in between the moving element and the oscillator.

6. The oscillation actuator according to claim 1,
wherein the oscillator has an abutting surface which contacts the moving element,
the moving element has an opposing surface which contacts the abutting surface of the oscillator, and
the opposing surface of the moving element has a recess section.

7. The oscillation actuator according to claim 6, wherein the opposing surface of the moving element has a flat section which makes surface contact with the abutting surface of the oscillator, and the recess section has a plurality of holes capable of holding lubricant.

8. The oscillation actuator according to claim 6, wherein the recess section has at least one groove formed in the opposing surface of the moving element and capable of holding lubricant.

9. The oscillation actuator according to claim 8, wherein the recess section has a plurality of the grooves, and the grooves have a plurality of intersecting groove directions.

10. The oscillation actuator according to claim 6,
wherein the oscillator has a projecting claw section which projects,
the abutting surface is formed on one portion of a surface of the projecting claw section,
the lubricant supply unit contacts at least one portion of the projecting claw section, and
the abutting surface has a plurality of grooves capable of holding lubricating oil.

11. The oscillation actuator according to claim 2, wherein the supply body is a porous member.

12. The oscillation actuator according to claim 1, wherein the vibration of the oscillation unit is controlled in such a manner that an antinode position of the vibration or the vicinity of the antinode of the vibration is contained in the abutting surface of the oscillator.

13. The oscillation actuator according to claim 1,
wherein the moving element has a moving element-side contact surface capable of contacting the oscillator,
the oscillator has an oscillator-side contact surface capable of contacting the moving element-side contact surface, and
a ratio (A/B) between a hardness (A) of the moving element-side contact surface and a hardness (B) of the oscillator-side contact surface is greater than 1 and no greater than 20.

14. The oscillation actuator according to claim 1,
wherein the oscillator has a mounting section which contacts the moving element,
the moving element has a cylindrical shape to rotate in contact with the mounting section of the oscillator, and has an opposing surface which contacts the mounting section of the oscillator, and
a point contact region where the oscillator and the moving element make point contact in a thickness direction of the moving element is provided in the region of opposition between the mounting section of the oscillator and the opposing surface of the moving element.

15. The oscillation actuator according to claim 14, wherein the point contact region is provided by forming a curved surface which is curved in the thickness direction of the moving element, or a tapered surface which is inclined with respect to the thickness direction of the moving element, in the mounting section of the oscillator.
